(19) United States
(12) Patent Application Publication
(10) Pub. No.: US 2025/0336636 A1
(43) Pub. Date: Oct. 30, 2025

(54) METHOD AND SYSTEM FOR FINE FOCUSING SECONDARY BEAM SPOTS ON DETECTOR FOR MULTI-BEAM INSPECTION APPARATUS

(71) Applicant: ASML Netherlands B.V., Veldhoven (NL)

(72) Inventors: Oleg KRUPIN, San Jose, CA (US); Weiming REN, San Jose, CA (US); Xiaoyu JI, San Jose, CA (US); Zizhou GONG, San Jose, CA (US); Xuerang HU, San Jose, CA (US); Xuedong LIU, San Jose, CA (US)

(73) Assignee: ASML Netherlands B.V., Veldhoven (NL)

(21) Appl. No.: 18/866,014

(22) PCT Filed: Jul. 11, 2023
(86) PCT No.: PCT/EP2023/069140

§ 371 Date: Nov. 14, 2024

Related U.S. Application Data
(60) Provisional application No. 63/368,597, filed on Jul. 15, 2022.

(51) Int. Cl. H01J 37/21; H01J 37/244; H01J 37/26; H01J 37/28

(52) U.S. Cl. CPC H01J 37/21; H01J 37/244; H01J 37/265; H01J 37/28; H01J 2237/0453; H01J 2237/10; H01J 2237/2448; H01J 2237/2817

(57) ABSTRACT

Systems and methods of measuring of optimizing collection efficiency of secondary charged particles include a multi-beam inspection apparatus configured to scan a sample and including a lens, a detector configured to receive a plurality of secondary charged-particle beams in response to scanning the sample, and a controller including circuitry communicatively coupled to the multi-beam inspection apparatus and the detector, configured to: focus the lens to adjust sizes of secondary beam spots, wherein the secondary beam spots are formed by the plurality of secondary charged-particle beams on the detector; cause, for each secondary charged-particle beam of the plurality of secondary charged-particle beams, outlier charged particles of the each secondary charged-particle beam to not be detected by the detector; and refocus the lens to adjust currents of a portion of the plurality of secondary charged-particle beams detected by the detector, wherein the outlier charged particles do not contribute to the currents.

### CROSS-REFERENCE TO RELATED APPLICATIONS

This application claims priority of U.S. application 63/368,597 which was filed on 15 Jul. 2022 and which is incorporated herein in its entirety by reference.

FIELD

The description herein relates to the field of image inspection apparatus, and more particularly

to methods and systems for fine focusing secondary beam spots on a detector for a multi-beam inspection apparatus.

### BACKGROUND

An image inspection apparatus (e.g., a charged-particle beam apparatus or an optical beam apparatus) is able to produce a two-dimensional (2D) image of a wafer substrate by detecting particles (e.g., secondary electrons, backscattered electrons, other kinds of electrons or photons) from a surface of a wafer substrate upon scanning the surface with one or more beams (e.g., including a charged-particle beam or an optical beam) generated by a source associated with the inspection apparatus. Various image inspection apparatuses are used on semiconductor wafers in the semiconductor industry for various purposes such as critical dimension measurements (CD-SEM), wafer inspection (e.g., e-beam inspection system), or defect analysis (e.g., defect review SEM (DR-SEM)).

In semiconductor manufacturing, to control the quality of manufactured structures on the wafer substrate and to detect potential defects, the 2D images of the wafer may be recorded and analyzed. As the physical sizes of IC components continue to shrink, accuracy and yield in defect detection become more and more critical. An essential aspect of increasing the throughput and accuracy of defect detection is utilizing multiple beams to scan a plurality of regions on the wafer surface simultaneously. This concept is realized in multi-beam scanning inspection systems, e.g., multi-beam SEM systems.

For multi-beam inspection systems, the collection efficiency of the secondary electrons and crosstalk between the secondary electron beamlets are two essential parameters. For the best performance, the collection efficiency should be maximized, while crosstalk should be minimized. The collection efficiency depends on methods of fine focusing secondary charged particles forming the spots on the detector. Optimization of the methods of fine focusing the secondary charged particles may increase the collection efficiency and, eventually, increase the yield in defect detection.

### SUMMARY

Embodiments of the present disclosure provide systems and methods of optimizing collection efficiency of secondary charged particles. In some embodiments, a system may include a multi-beam inspection apparatus configured to scan a sample and includes a lens, a detector configured to receive a plurality of secondary charged-particle beams in response to scanning the sample, and a controller including circuitry communicatively coupled to the multi-beam inspection apparatus and the detector. The controller may be configured to focus the lens to adjust sizes of secondary beam spots, wherein the secondary beam spots are formed by the plurality of secondary charged-particle beams on the detector. The controller may also be configured to cause, for each secondary charged-particle beam of the plurality of secondary charged-particle beams, outlier charged particles of the each secondary charged-particle beam to not be detected by the detector. The controller may be further configured to refocus the lens to adjust currents of a portion of the plurality of secondary charged-particle beams detected by the detector, wherein the outlier charged particles do not contribute to the currents.

In some embodiments, a non-transitory computer-readable medium may store a set of instructions that is executable by at least one processor of a multi-beam inspection apparatus to cause the multi-beam inspection apparatus to perform a method. The method may include focusing a lens of the multi-beam inspection apparatus to adjust sizes of secondary beam spots, wherein the secondary beam spots are formed by a plurality of secondary charged-particle beams on a detector. The method may also include causing, for each secondary charged-particle beam of the plurality of secondary charged-particle beams, outlier charged particles of the each secondary charged-particle beam to not be detected by the detector. The method may further include refocusing the lens to adjust currents of a portion of the plurality of secondary charged-particle beams detected by the detector, wherein the outlier charged particles do not contribute to the currents.

In some embodiments, a method of optimizing collection efficiency of secondary charged particles may include focusing a lens of the multi-beam inspection apparatus to adjust sizes of secondary beam spots, wherein the secondary beam spots are formed by a plurality of secondary charged-particle beams on a detector. The method may also include causing, for each secondary charged-particle beam of the plurality of secondary charged-particle beams, outlier charged particles of the each secondary charged-particle beam to not be detected by the detector. The method may further include refocusing the lens to adjust currents of a portion of the plurality of secondary charged-particle beams detected by the detector, wherein the outlier charged particles do not contribute to the currents.

### BRIEF DESCRIPTION OF THE DRAWINGS

FIG. 1 is a schematic diagram illustrating an example charged-particle beam inspection (CPBI) system, consistent with some embodiments of the present disclosure.

FIG. 2 is a schematic diagram illustrating an example multi-beam beam tool that may be a part of the example charged-particle beam inspection system of FIG. 1, consistent with some embodiments of the present disclosure.

FIG. 3 is a schematic diagram illustrating an example secondary projection system that may be a part of the example multi-beam beam tool of FIG. 2, consistent with some embodiments of the present disclosure.

FIG. 4A is a schematic diagram illustrating an example of paraxial focusing approach of a charged-particle beam, consistent with some embodiments of the present disclosure.

FIG. 4B is a schematic diagram illustrating an example of least-confusion focusing approach of a charged-particle beam, consistent with some embodiments of the present disclosure.

FIG. 5A is a graph visualizing a cross-section of an example charged-particle beam on a plane of a beam limiting aperture, consistent with some embodiments of the present disclosure.

FIG. 5B is a graph illustrating a profile of the example charged-particle beam of FIG. 5A, consistent with some embodiments of the present disclosure.

FIG. 6 is a graph illustrating example beam spot size optimization using different beam focusing approaches, consistent with some embodiments of the present disclosure.

FIG. 7 is a graph illustrating example signal intensity distributions of secondary beam spots corresponding to different beam focusing approaches, consistent with some embodiments of the present disclosure.

FIG. 8A is a graph illustrating example integrated signal intensities of secondary beam spots corresponding to different beam focusing approaches, consistent with some embodiments of the present disclosure.

FIG. 8B is a graph illustrating differences between example integrated signal intensities of secondary beam spots corresponding to different beam focusing approaches, consistent with some embodiments of the present disclosure.

FIG. 9 is a graph illustrating profiles of example secondary beam spots on a plane of a beam limiting aperture corresponding to different beam focusing approaches, consistent with some embodiments of the present disclosure.

FIG. 10A is a graph illustrating example integrated signal intensities of secondary beam spots corresponding to different beam focusing approaches, consistent with some embodiments of the present disclosure.

FIG. 10B is a graph illustrating differences between example integrated signal intensities of secondary beam spots corresponding to different beam focusing approaches, consistent with some embodiments of the present disclosure.

FIG. 11 is a flowchart illustrating an example method of optimizing collection efficiency of secondary charged particles, consistent with some embodiments of the present disclosure.

### DETAILED DESCRIPTION

Reference will now be made in detail to example embodiments, examples of which are illustrated in the accompanying drawings. The following description refers to the accompanying drawings in which the same numbers in different drawings represent the same or similar elements unless otherwise represented. The implementations set forth in the following description of example embodiments do not represent all implementations consistent with the disclosure. Instead, they are merely examples of apparatuses and methods consistent with aspects related to the subject matter recited in the appended claims. Without limiting the scope of the present disclosure, some embodiments may be described in the context of providing detection systems and detection methods in systems utilizing electron beams (“e-beams”). However, the disclosure is not so limited. Other types of charged-particle beams (e.g., including protons, ions, or any other particle carrying electric charges) may be similarly applied. Furthermore, systems and methods for detection may be used in other measurement systems, such as optical imaging, photon detection, x-ray detection, ion detection, or the like.

Microchips are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them may be fit on the substrate. For example, an IC chip in a smartphone may be as small as a thumbnail and yet may include over 2 billion transistors, the size of each transistor being less than 1/1000th the size of a human hair.

Making these ICs with extremely small components and structures is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process. One way to monitor the process is to inspect the chip circuit structures at various stages of their formation. Inspection may be carried out using a scanning charged-particle microscope (“SCPM”). For example, a scanning charged-particle microscope may be a scanning electron microscope (SEM). A scanning charged-particle microscope may be used to image these extremely small structures, in effect, taking a “picture” of the structures of the wafer. The image may be used to determine if the structure was formed properly in the proper location. If the structure is defective, then the process may be adjusted, so the defect is less likely to recur.

In a single-beam SEM, a surface image may be created by scanning an inspected area with a focused primary-electron beam line by line. When the primary-electron beam hits the surface, a spot, which may be referred to as a “probe spot,” is formed where secondary electrons and back-scattered electrons are emitted in response to the primary beam. In this disclosure, unless expressly described, the term “secondary electrons” may encompass the secondary electrons or may encompass both the secondary electrons and the back-scattering electrons. The surface image may be reconstructed by collecting the secondary electrons emitted from the probe spot on the surface. A relationship between secondary-electron intensity and the probe spot's position may be determined. Such a relationship may also be presented (e.g., as a two-dimensional plot). Creating a high-resolution image of the surface line by line may be a slow process even if the SEM scanning rate is high. As a result, the wafer inspection may be very time-consuming.

Multi-beam SEM systems can improve measurement speed and achieve higher throughput for wafer inspection applications. In a multi-beam SEM, an array of primary-electron beams (or referred to as “beamlets”) may be formed to scan a plurality of the sub-regions within an inspected area simultaneously. Each of the primary-electron beamlets may form a probe spot on a sub-region of the inspected area, and the formed probe spots may form an array corresponding to the array of primary-electron beamlets. Multiple secondary-electron beamlets originating at the probe spots may be formed and directed to a detector via a secondary-electron column. The detector may include an array of electron-detecting elements (referred to as “detector elements” herein). The array of detector elements may be implemented as an array of individual sensors, as a two-dimensional pixelated detector, or any other form. If the array of detector elements are implemented as a two-dimensional pixelated detector, each of the detector elements may be implemented as a different group of pixels. Each group of pixels may be referred to as a detector element (or alternatively referred to as a “detector cell”) in this disclosure, and the pixels which form the group that form the detector cell may be configurable (e.g., via a switch network between the pixels). The secondary-electron column may be configured so that each detector element may detect intensity of a secondary-electron beamlet corresponding to one of the probe spots, which further correspond to a sub-region of the inspected area.

In this disclosure, a collection efficiency of a single detector element refers to a fraction of secondary electrons emitted from a probe spot within one of the sub-regions of the inspected area and detected by the corresponding detection element, or refers to a ratio between the numbers of the detected and emitted electrons. For characterization of the whole detector, the average, minimum, or maximum values of the collection efficiency across all detector elements can be used.

In this disclosure, crosstalk refers to a fraction of secondary electrons detected by an individual detector element originating not from its corresponding sub-region of the inspected area, but rather, for example, from one or more of its neighboring sub-regions, or refers to a ratio between the number of detected electrons originating not from a corresponding sub-region and a total number of electrons detected by an individual detector element.

A high crosstalk value may reduce the performance of the multi-beam charged-particle inspection system. To reduce the crosstalk, several techniques may be adopted. For example, a beam-limiting aperture (or “BLA”) may be positioned at a point along the secondary-electron optical path between the wafer surface and the detector (e.g., right in front of the detector) to cut off tails of a secondary-electron beam distribution of a beam spot. All charged-particles outside the beam-limiting aperture may be collectively referred to as a “tail” of a beam spot in this disclosure. The tail of the beam spot may strongly contribute to the crosstalk at the detector. As another example, if the detector is a detector array (e.g., a pixel detector) that includes an array of detector elements (e.g., sub-units, cells, or groups of pixelated detector elements), a size of the detector element (e.g., a size of a detector cell) may be set to be a limited size to reduce the crosstalk (e.g., by reducing the size of the detector element to reduce an amount of “tail” electrons that are collected by the detector element). The addition of the beam-limiting aperture or the limitation of the size of the detector element may be used to reduce the crosstalk while also reducing the collection efficiency. Because of that, the collection efficiency may be limited by a predetermined level of the crosstalk. To maximize the throughput of the multi-beam charged-particle inspection system and the accuracy of defect detection, in some embodiments it may be of primary importance to maximize the collection efficiency at a predetermined level of the crosstalk ratio for any combination of parameters of the multi-beam charged-particle inspection system.

Maximization of the collection efficiency is challenging. In many existing technical solutions, a standard approach for focusing charged-particle beam spots on a detector is to minimize sizes of the beam spots without considering detector element sizes and without use of a beam-limiting aperture. Focusing parameters (e.g., excitations of focusing lenses) are typically fixed after such a minimization process. However, after fixing the focusing parameters to minimize the sizes of the beam spots, if the crosstalk ratio is still overly high, the crosstalk may be suppressed by adding a beam-limiting aperture or limiting sizes of detector elements. In such cases, the collection efficiency may not reach its theoretically possible maximum because the focusing parameters are fixed before adding the beam-limiting aperture or limiting the sizes of the detector elements.

Embodiments of the present disclosure may provide methods, apparatuses, and systems of optimizing collection efficiency of secondary charged particles. In some disclosed embodiments, during optimization of the focusing parameters of the multi-beam inspection apparatus, one or more lenses may be focused to adjust (e.g., to minimize) spot sizes of multiple secondary beams on the detector. Also, outlier charged particles of each of the multiple secondary beams may be caused to not be detected by the detector (e.g., by using a beam-limiting aperture, limiting a size of a detector element, etc.). Then, a focus parameter of the lens may be adjusted to adjust (e.g., to maximize) currents of a portion of the multiple secondary beams detected by the detector, in which the portion of the multiple secondary beams detected by the detector and having the maximized currents do not include the outlier charged particles. Compared with existing techniques, while suppressing or reducing the crosstalk to be under a predetermined level, the collection efficiency corresponding to the predetermined level of crosstalk may be increased or maximized with consideration of sizes of the detector elements or whether a beam-limiting aperture is used.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

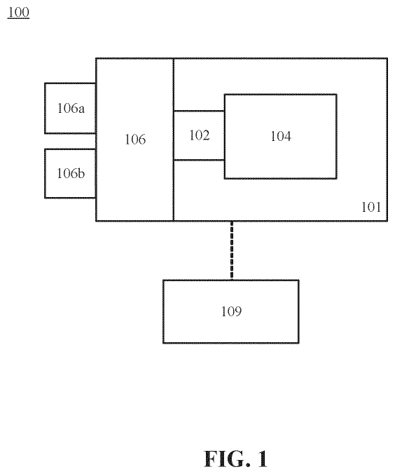

FIG. 1 illustrates an example charged-particle beam inspection (CPBI) system 100 consistent with some embodiments of the present disclosure. CPBI system 100 may be used for imaging. For example, CPBI system 100 may use an electron beam for imaging. As shown in FIG. 1, CPBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system. Typically, within the CPBI system a wafer is placed on a platform. The platform may be referred to as a “stage” in this disclosure.

A controller 109 is electronically connected to beam tool 104. Controller 109 may be a computer that may execute various controls of CPBI system 100. While controller 109 is shown in FIG. 1 as being outside the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

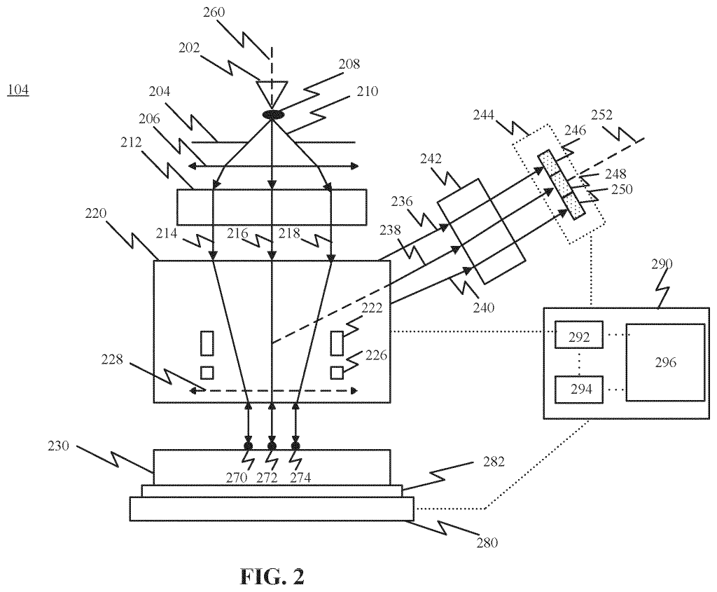

In some embodiments, beam tool 104 may be a multi-beam system. By way of example, FIG. 2 illustrates a schematic diagram of an example multi-beam beam tool 104 (also referred to herein as apparatus 104) and an image processing system 290 that may be used in CPBI system 100 in FIG. 1, consistent with embodiments of the present disclosure.

With reference to FIG. 2, beam tool 104 includes a charged-particle source 202, a gun aperture 204, a condenser lens 206, a primary charged-particle beam 210 emitted from charged-particle source 202, a source conversion unit 212, a plurality of primary beamlets of primary charged-particle beam 210 (including primary beamlets 214, 216, and 218), a primary projection system 220 motorized wafer stage 280, a wafer holder 282, multiple secondary beamlets 236, 238, and 240, a secondary projection system 242, and a charged-particle detector 244. Primary projection system 220 may include a beam separator 222, a deflection scanning unit 226, and an objective lens 228. Charged-particle detector 244 may include detector elements 246, 248, and 250.

Charged-particle source 202, gun aperture 204, condenser lens 206, source conversion unit 212, beam separator 222, deflection scanning unit 226, and objective lens 228 may be aligned with a primary projection axis 260 (e.g., similar to a primary optical axis in an optical system) of apparatus 104. Secondary projection system 242 and charged-particle detector 244 may be aligned with a secondary projection axis 252 (e.g., similar to a secondary optical axis in an optical system) of apparatus 104.

Charged-particle source 202 may emit one or more charged particles, such as electrons, protons, ions, or any other particle carrying electric charges. In some embodiments, charged-particle source 202 may be an electron source. For example, charged-particle 202 may include a cathode, an extractor, or an anode. Primary electrons may be emitted from the cathode and extracted or accelerated to form primary charged-particle beam 210 (e.g., a primary electron beam) with a crossover 208 (e.g., being virtual or real). Primary charged-particle beam 210 may be visualized as being emitted from crossover 208 in FIG. 2. Gun aperture 204 may block off peripheral charged particles of primary charged-particle beam 210 to reduce Coulomb effect. The Coulomb effect may cause an increase in size of probe spots.

Source conversion unit 212 may include an array of image-forming elements and an array of beam-limiting apertures. The array of image-forming elements may include an array of micro-deflectors or micro-lenses. The array of image-forming elements may form a plurality of parallel images (virtual or real) of crossover 208 with multiple primary beamlets of primary charged-particle beam 210 (including primary beamlets 214, 216, and 218). The array of beam-limiting apertures may limit the plurality of beamlets 214, 216, and 218. While three primary beamlets 214, 216, and 218 are shown in FIG. 2, embodiments of the present disclosure are not so limited.

Condenser lens 206 may focus primary charged-particle beam 210. The electric currents of primary beamlets 214, 216, and 218 downstream of source conversion unit 212 may be varied by adjusting the focusing power (e.g., excitations) of condenser lens 206 or by changing the radial sizes of the corresponding beam-limiting apertures within the array of beam-limiting apertures. Objective lens 228 may focus primary beamlets 214, 216, and 218 onto a sample 230 for imaging, and may form a plurality of probe spots (including probe spots 270, 272, and 274) on or near a surface of sample 230 (e.g., a wafer).

By way of example, charged-particle source 202 may be an electron source, and primary beamlets 214, 216, and 218 may be electron beamlets. A primary electron beamlet may penetrate the surface of sample 230 for a certain depth (e.g., from several nanometers to several micrometers), interacting with particles of sample 230. Some electrons of the primary electron beamlet may elastically interact with (e.g., in a form of elastic scattering) the particles of sample 230 and may be reflected or recoiled out of the surface of sample 230. An elastic interaction conserves the kinetic energies of the interacting bodies of the interaction (e.g., the electrons of primary electron beamlet and the particles of sample 230), in which no kinetic energy of the interacting bodies convert to other forms of energy (e.g., heat). Such reflected electrons generated from elastic interaction may be referred to as backscattered electrons (BSEs). Also, some electrons of the primary electron beamlet may inelastically interact with (e.g., in a form of inelastic scattering) the particles of sample 230. An inelastic interaction does not conserve the kinetic energies of the interacting bodies, in which some or all of the kinetic energy of the interacting bodies may covert to other forms of energy. For example, the inelastic interaction may ionize some particles of sample 230, and the ionized particles may generate additional electrons, which may be referred to as secondary electrons (SEs). The secondary electrons may exit the surface of sample 230. Yield or emission rates of BSEs and SEs may depend on, for example, the energy of the electrons of the primary electron beamlet and the material of sample 230, among other factors. The quantity of BSEs and SEs may be more than, fewer than, or the same as the injected electrons of the primary electron beamlet. For ease of explanation in unambiguous contexts, unless explicitly stated, backscattered electrons and secondary electrons may be referred to as “secondary electrons” hereinafter. Also, as used herein, a “probe spot” (e.g., probe spot 270, 272, or 274) refers to an area on or near a surface of a sample under inspection, in which the area emits secondary charged particles (e.g., secondary electrons) corresponding to an incident charged-particle beam or beamlet.

Still referring to FIG. 2, beam separator 222 may include a beam separator (e.g., being of a type of Wien filter) that generates an electrostatic dipole field and a magnetic dipole field. In some embodiments, the force exerted by the electrostatic dipole field on a charged particle (e.g., an electron) of primary beamlets 214, 216, and 218 may be substantially equal to, with the same magnitude and opposite direction, the force exerted on the charged particle by the magnetic dipole field. Primary beamlets 214, 216, and 218 may, accordingly, pass straight through beam separator 222 with a zero deflection angle. In some cases, the total dispersion of primary beamlets 214, 216, and 218 generated by beam separator 222 may also be non-zero.

Deflection scanning unit 226 may deflect primary beamlets 214, 216, and 218 to scan over a surface area of sample 230. In response to the incidence of primary beamlets 214, 216, and 218, secondary charged-particle beams (including secondary beamlets 236, 238, and 240) may be emitted from sample 230 at probe spots 270, 272, and 274. Secondary beamlets 236, 238, and 240 may include charged particles (e.g., electrons) with a distribution of energies and an upward moving direction. When the secondary beamlets (e.g., including secondary beamlets 236, 238, and 240) enter primary projection system 220, beam separator 222 may separate the secondary beamlets from the primary beamlets (e.g., primary beamlets 214, 216, and 218), and further direct the secondary beamlets towards secondary projection system 242.

Secondary projection system 242 may focus secondary beamlets 236, 238, and 240 onto detector elements 246, 248, and 250 of charged-particle detector 244. A single detector element (e.g., detector element 246, 248, or 250) may be designed to detect a single corresponding secondary beamlet (e.g., secondary beamlets 236, 238, or 240, respectively) originating from a single probe spot (e.g., probe spots 270, 272, or 274, respectively) and to generate a corresponding signal (e.g., voltage, current, etc.) to reconstruct an image of the scanned surface of sample 230. In some embodiments, charged-particle detector 244 may include an array of individual sensors, in which a single detector element (e.g., detector element 246, 248, or 250) may be a single sensor. In some embodiments, charged-particle detector 244 may include a 2D pixelated detector that includes an array of detector cells, in which a single detector element (e.g., detector element 246, 248, or 250) may be implemented as a group of pixels (e.g., each pixel representing a single detector cell).

The generated signals may represent intensities of secondary beamlets 236, 238, and 240 and may be provided to image processing system 290 in communication with (represented by dotted lines in FIG. 2) charged-particle detector 244, primary projection system 220, and motorized wafer stage 280. The intensity of secondary beamlets 236, 238, and 240 may vary according to the external or internal structure of sample 230, and thus may indicate whether sample 230 includes defects. Moreover, primary beamlets 214, 216, and 218 may be projected onto different locations of the top surface of sample 230, to generate secondary beamlets 236, 238, and 240 of different intensities. Therefore, by mapping the intensity of secondary beamlets 236, 238, and 240 with the areas of sample 230, image processing system 290 may reconstruct an image that reflects the characteristics of internal or external structures of sample 230.

In some embodiments, image processing system 290 may include an image acquirer 292, a storage 294, and a controller 296. Image acquirer 292 may include one or more processors. For example, image acquirer 292 may include a computer, server, mainframe host, terminals, personal computer, any kind of mobile computing devices, or the like, or a combination thereof. Image acquirer 292 may be communicatively coupled to charged-particle detector 244 of beam tool 104 through a medium such as an electric conductor, optical fiber cable, portable storage media, IR, Bluetooth, internet, wireless network, wireless radio, or a combination thereof. In some embodiments, image acquirer 292 may receive a signal from charged-particle detector 244 and may construct an image. Image acquirer 292 may thus acquire images of sample 230. Image acquirer 292 may also perform various post-processing functions, such as generating contours, superimposing indicators on an acquired image, or the like. Image acquirer 292 may be configured to perform adjustments of brightness and contrast of acquired images. In some embodiments, storage 294 may be a storage medium such as a hard disk, flash drive, cloud storage, random access memory (RAM), other types of computer-readable memory, or the like. Storage 294 may be coupled with image acquirer 292 and may be used for saving scanned raw image data as original images, and post-processed images. Image acquirer 292 and storage 294 may be connected to controller 296. In some embodiments, image acquirer 292, storage 294, and controller 296 may be integrated together as one control unit.

In some embodiments, image acquirer 292 may acquire one or more images of a wafer based on an imaging signal received from charged-particle detector 244. An imaging signal may correspond to a scanning operation for conducting charged particle imaging. An acquired image may be a single image including a plurality of imaging areas. The single image may be stored in storage 294. The single image may be an original image that may be divided into a plurality of regions. Each of the regions may include one imaging area containing a feature of sample 230. The acquired images may include multiple images of a single imaging area of sample 230 sampled multiple times over a time sequence. The multiple images may be stored in storage 294. In some embodiments, image processing system 290 may be configured to perform image processing steps with the multiple images of the same location of sample 230.

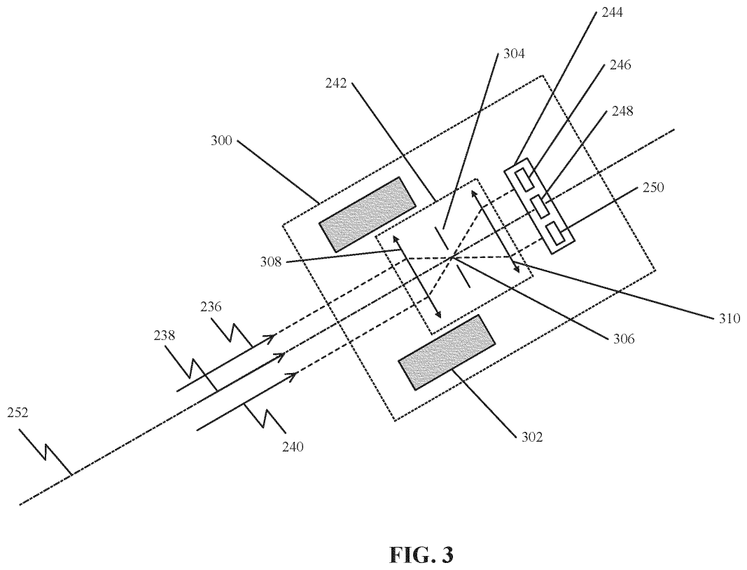

By way of example, FIG. 3 is a schematic diagram illustrating an example secondary column 300 that may be a part of beam tool 104 of FIG. 2, consistent with some embodiments of the present disclosure. For example, secondary column 300 may include charged-particle detector 244. Secondary column 300 may also include an anti-scanning deflection system 302 and secondary projection system 242. In some embodiments, secondary column 300 may further include one or more focusing lenses (including a lens 308 and a lens 310) and a beam separator (not shown in FIG. 3). The one or more focusing lenses may be objective lenses, such as an objective lens the same as or similar to objective lens 228 of FIG. 2. The one or more focusing lenses may collect secondary charged particles emitted from the probe spots and forms the secondary beamlets (including secondary beamlets 236, 238, and 240). As illustrated in FIG. 3, charged-particle detector 244 further includes detector elements 246, 248, and 250. Detector elements 246, 248, and 250 may be designed to detect corresponding secondary beamlets 236, 238, and 240, respectively. Secondary beamlets 236, 238, and 240 in FIG. 3 may originate from probe spots 270, 272, or 274 illustrated in FIG. 2, respectively. Components of secondary column 300 may be aligned with secondary projection axis 252.

In some embodiments, lens 308 may be used to set magnification, and lens 310 may be used for image focusing. Either lens 308 or lens 310 may be referred to as a “focusing lens” in the meaning that both contribute to focusing the secondary beamlets. The beam separator (e.g., being similar to or the same as beam separator 222) may direct the secondary beamlets toward secondary projection system 242. Anti-scanning deflection system 302 may direct all secondary beamlets toward secondary projection axis 252 to minimize image displacement on charged-particle detector 244. For example, with reference to FIG. 2, the image displacement may originate from motion of the probe spots (e.g., including probe spots 270, 272, and 274 of FIG. 2) across an inspected area of sample 230 in step with deflection scanning unit 226.

Secondary projection system 242 may project the secondary beamlets (e.g., including secondary beamlets 236, 238, and 240), maintaining their characteristics (e.g., including focuses, sizes, and rotations), onto charged-particle detector 244. Secondary projection system 242 may maintain the characteristics of the secondary beamlets as nearly constant and independent of imaging conditions of beam tool 104 of FIG. 2. As illustrated in FIG. 3, secondary projection system 242 includes a beam-limiting aperture 304. Beam-limiting aperture 304 has a radius, and the radius may determine which portion of the secondary beamlets is permitted to reach charged-particle detector 244.

Similar to an optical system, electron-optical elements of secondary column 300 may have aberrations. Such aberrations may blur the image projected by secondary projection system 242 on charged-particle detector 244 and limit detection performance. The aberrations may also incur or increase the crosstalk as described herein and limit the collection efficiency of charged-particle detector 244.

To suppress the crosstalk, as illustrated in FIG. 3, beam-limiting aperture 304 may be positioned at or near a crossover 306 at secondary projection axis 252. Beam-limiting aperture 304 may cut off outlier electrons of the secondary beamlets, and only central parts of the secondary beamlets may reach charged-particle detector 244. By use of beam-limiting aperture 304, rims of spots of the secondary beamlets formed on detector elements (e.g., including detector elements 244, 246, and 248) may be cut off. Accordingly, sizes of the spots of the secondary beamlets formed on detector elements may be limited, thereby reducing the crosstalk. It should be noted that the usage of beam-limiting aperture 304 may also limit the collection efficiency.

Consistent with some embodiments of this disclosure, a method of optimizing collection efficiency of secondary charged particles may include focusing a lens (e.g., one or more focusing lenses) of a multi-beam inspection apparatus to adjust (e.g., to minimize) sizes of secondary beam spots. The secondary beam spots may be formed by a plurality of secondary charged-particle beams (e.g., secondary electron beams) on a detector. In some embodiments, the multi-beam inspection apparatus may include a multi-beam scanning electron microscope (SEM). In some embodiments, the detector may include a charged-particle detector (e.g., an electron detector).

A lens, as used herein, may refer to a focusing lens or a set of focusing lenses of an electron projection-imaging system (e.g., a secondary-electron projection-imaging system) or any functionally equivalent component. Focusing a lens, as used herein, may refer to any operation (e.g., under control of a controller or processor) to increase, decrease, or maintain a focusing power (e.g., a refractive power) of the lens. For example, if the lens is an electrostatic lens (or a magnetic lens, or a compound lens), excitations of the lens may be set to increase, decrease, or maintain the focusing power of the lens.

A secondary charged-particle beam, as used herein, may refer to a beam formed by secondary charged particles exiting from a probe spot on or near a surface of a sample (e.g., a wafer) under inspection by the multi-beam inspection apparatus in response to a primary charged-particle beam incident onto the probe spot. For example, if the multi-beam inspection apparatus is a multi-beam SEM, the secondary charged-particle beam may be a secondary electron beam formed by secondary electrons and backscattered electrons exiting from a probe spot in response to a primary electron beam incident onto the probe spot.

A secondary beam spot in this disclosure may refer to an image of a wafer probe spot (i.e., a probe spot on a wafer) formed by a secondary-electron beam on a detector. A size of the secondary beam spot may depend on various factors, such as a focusing power of the lens, an incident angular distribution of the secondary charged-particle beam, or the like.

By way of example, with reference to with FIGS. 2-3 and their associated descriptions, the multi-beam inspection apparatus may be a multi-beam beam tool (e.g., beam tool 104 in FIG. 2). The focusing lens may be, for example, the last lens (e.g., lens 310 in FIG. 3) in the secondary column (e.g., secondary column 300 in FIG. 3) before the detector. The plurality of secondary charged-particle beams may include secondary beamlets 236, 238, and 240. The detector may be charged-particle detector 244. The secondary beam spots may be images of wafer probe spots formed by the plurality of secondary charged-particle beams on charged-particle detector 244.

In some embodiments, to focus the lens (e.g., lens 310 in FIG. 3) of the multi-beam inspection apparatus to adjust the sizes of the secondary beam spots, various approaches may be performed. For example, if the detector is a pixelated detector, to cause the outlier charged particles not to be detected by the detector, a number of pixels of a detector cell of the detector may be adjusted, in which the pixels of the detector cell may be used for detecting the plurality of secondary charged-particle beams. When a secondary charged-particle beam is projected by the lens onto a surface of the pixelated detector and form a beam spot, pixels covered by the beam spot may respond and generate signals representing secondary-electron beam intensities. The number of responding pixels may be proportional to the size of the beam spot. To adjust the size of the beam spot, the lens may be focused to adjust the number of pixels of the pixelated detector that respond to the beam spot.

As another example, to adjust the sizes of the secondary beam spots, the lens may be focused to cause paraxial rays of the plurality of secondary charged-particle beams to focus on a plane of the detector. A paraxial ray of a charged-particle beam, as used herein, may refer to a charged-particle ray that belongs to the charged-particle beam and is close to a projection axis of a lens such that an approximation sin θ≈θ is valid, in which the charged-particle beam is refracted by the lens, and θ represents an angle of refraction of the charged-particle ray. Such a focusing approach may be referred to as “paraxial focusing approach” in this disclosure.

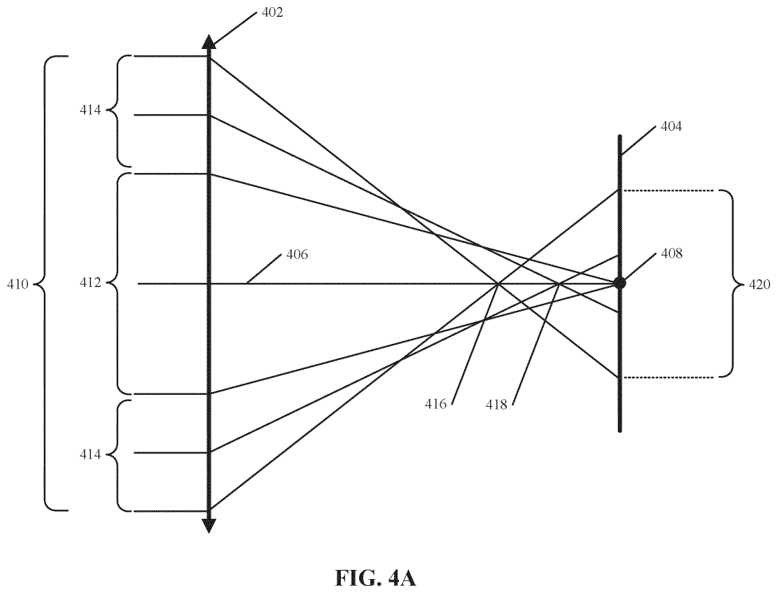

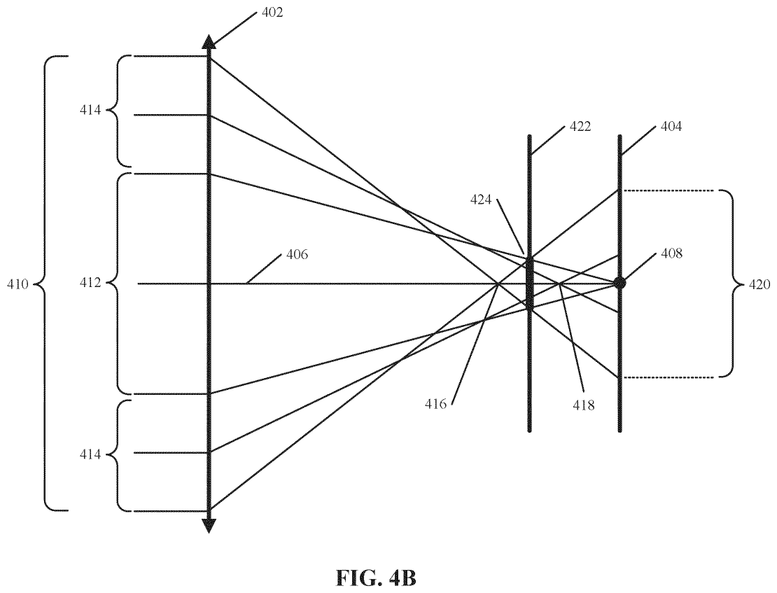

By way of example, FIG. 4A is a schematic diagram illustrating an example of paraxial focusing approach of a charged-particle beam, consistent with some embodiments of the present disclosure. FIG. 4A depicts a focusing lens 402 (represented by a bold double arrow) and a focal plane 404 (represented by a bold line). Focusing lens 402 has a projection axis 406 (similar to an optical axis of an optical lens) and a focal point 408 (represented by a black dot). Focal point 408 is on focal plane 404. Focal plane 404 may be placed (e.g., by adjusting the focusing power of objective lens 410) on or near a surface of a detector (not illustrated in FIG. 4A), in which case focal plane 404 may also be referred to as an image plane. It should be noted that the focal plane may coincide with the image plane only for the focusing of collimated beams (e.g., parallel beams). For converging or diverging beams, the image plane may only coincide with a plane of the detector (referred to as a “detector plane” herein).

As illustrated in FIG. 4A, a charged-particle beam 410 (e.g., an electron beam) is projected onto focusing lens 402 with an incident angle of 0° and is focused by focusing lens 402 towards focal point 408. Charged-particle beam 410 includes multiple charged-particle rays (represented by solid lines). In an ideal scenario (not illustrated in FIG. 4A), if charged-particle beam 410 is collimated (e.g., all incident charged-particle rays are parallel to each other) and focusing lens 402 is a perfect lens (e.g., having no aberration), all charged-particle rays of charged-particle beam 410 may be focused at or near (e.g., directed to) focal point 408. In a practical scenario (as illustrated in FIG. 4A), focusing lens 402 is not a perfect lens (e.g., having aberrations, such as spherical aberrations), some charged-particle rays of charged-particle beam 410 may not be focused at focal point 408.

As illustrated in FIG. 4A, charged-particle beam 410 includes paraxial rays 412 and marginal

rays 414. A marginal ray of a charged-particle beam, as used herein, may refer to a charged-particle ray that belongs to the charged-particle beam and is distanced to a projection axis of a lens such that an approximation sin θ≈θ is violated, in which the charged-particle beam is refracted by the lens, and θ represents an angle of refraction of the charged-particle ray. With reference to FIG. 4A, paraxial rays 412 are focused at focal point 408, and marginal rays 414 are focused at various points (including point 416 and 418) that are different from focal point 408. On focal plane 404, a beam spot 420 is formed by the focused charged-particle beam 410. It should be noted that, although FIG. 4A illustrates charged-particle beam 410 as a collimated beam, in a case (not illustrated in FIG. 4A) where charged-particle beam 410 is not collimated (e.g., being converging or diverging) before focusing lens 402, charged-particle beam 410 will be focused before or after focal point 408. In such a case, paraxial rays 412 and marginal rays 414 are still focused at different positions. For example, marginal rays 412 may be focused at a point before a point where paraxial rays 412 are focused along projection axis 406.

FIG. 4A illustrates an example paraxial focusing approach to minimize a size of beam spot 420. In FIG. 4A, focusing lens 402 is focused (e.g., by setting its excitations) to cause paraxial rays 412 to focus on a plane of a detector.

In some embodiments, to focus the lens of the multi-beam inspection apparatus to adjust the sizes of the secondary beam spots, as yet another example, the lens may be focused to position ellipses of least confusion of the plurality of secondary charged-particle beams on the plane of the detector to form the secondary beam spots. An ellipse of least confusion of a focused charged-particle beam, as used herein, refers to a spot of any shape (e.g., an oval shape or a round shape) formed on an image plane, and the spot is the smallest among all spots formed on all possible image planes. An ellipse in this disclosure includes any oval shape with two foci or a round shape (e.g., a circle) with a single focus.

The ellipse of least confusion may be determined when a first outer rim of projected marginal rays of the charged-particle beam overlaps with a second outer rim of projected paraxial rays of the charged-particle beam. The first outer rim and the second outer rim may be measured from the projection axis on the image plane. Such a focusing approach may be referred to as “least-confusion focusing approach” in this disclosure.

By way of example, FIG. 4B is a schematic diagram illustrating an example of least-confusion focusing approach of a charged-particle beam, consistent with some embodiments of the present disclosure. FIG. 4B illustrates an image plane 422 and an ellipse of least confusion 424 (represented by a thick bold line overlaying image plane 422) formed by focusing lens 402 projecting charged-particle beam 410 on image plane 422. It should be noted that, although FIG. 4B illustrates charged-particle beam 410 as a collimated beam, in a case (not illustrated in FIG. 4B) where charged-particle beam 410 is not collimated (e.g., being converging or diverging) before focusing lens 402, charged-particle beam 410 will be focused before or after focal point 408. In such a case, paraxial rays 412 and marginal rays 414 are still focused at different positions. For example, marginal rays 412 may be focused at a point before a point where paraxial rays 412 are focused along projection axis 406.

As illustrated in FIG. 4B, on image plane 422, ellipse of least confusion 424 is a spot that is the smallest among all spots formed on all possible image planes. Ellipse of least confusion 424 is determined when the outer rim of projected marginal rays 414 and the outer rim of projected paraxial rays 412 overlap. In the least-confusion focusing approach illustrated in FIG. 4B, focusing lens 402 is focused (e.g., by setting its excitations) to cause ellipse of least confusion 424 to be positioned on a plane of a detector (not illustrated in FIG. 4B) to form a beam spot. That is, in FIG. 4B, image plane 422 is the detector plane, and ellipse of least confusion 424 is the beam spot on the detector plane. For example, with reference to FIG. 4B, in a scenario that a distance between focusing lens 402 and the detector is fixed, to position ellipse of least confusion 424 (that is to the left of the detector plane) on the detector plane, the focusing power (e.g., a refractive power) of focusing lens 402 may be reduced to shift such that ellipse of least confusion 424 moves to the right towards the detector until ellipse of least confusion 424 is on the detector plane.

In some embodiments, to focus the lens of the multi-beam inspection apparatus to adjust the sizes of the secondary beam spots, as yet another example, the lens may be focused to minimize rising-edge widths of the secondary beam spots. To determine a rising-edge width of a beam spot, a signal intensity of the beam spot may be integrated along a direction from a first side of the beam spot to a second side of the beam spot to form a step function (e.g., a one-dimensional step function), in which the integrated signal intensity represents detected charge intensity. A rising edge of a step function, as used herein, refers to a portion of the step function, where a level of integrated signal intensity (that represents detected charge intensity) increases rapidly to form a step. A rising-edge width of a beam spot, as used herein, refers to a length of the rising edge of the step function. For example, the rising edge may be a portion of the step function in which a level of relative signal intensity (represented by percentages) increases, such as from 15% to 85%, or from 20% to 80%, or from 25 to 75% of a maximum level (e.g., 100% intensity level) of the step function. In a scenario where a charged-particle beam is well-focused, a rising-edge width of its beam spot may be small. In a scenario where a charged-particle beam is not well-focused, a rising-edge width of its beam spot may be large.

By way of example, to minimize rising-edge widths of the secondary beam spots, the focusing power (e.g., a refractive power) of a focusing lens (e.g., focusing lens 402 in FIGS. 4A-4B) may be adjusted (e.g., increased or decreased) to shift focal point 408 ahead, behind, or at the detector plane. During this process, the rising-edge widths of the secondary beam spots may be measured and recorded, and such adjustment may be stopped when the rising-edge widths of the secondary beam spots reach minimum values among all recorded values in a predetermined time interval. Such a focusing approach may be referred to as “minimal-rising-edge focusing approach” in this disclosure.

In some embodiments, to find excitation of focusing the lens of the multi-beam inspection apparatus to adjust the sizes of the secondary beam spots, a simulation process may be performed to optimize distribution of the secondary beam spots on the detector. For example, such a simulation process may be performed by projecting a set of test rays (e.g., including a chief ray, paraxial rays, marginal rays, or any combination thereof) onto a lens in a simulation model, and adjust parameters of the simulation model to adjust (e.g., to minimize) values of one or more predetermined merit functions. As an example, maximum radii of the secondary beam spots may be used as the merit functions.

Consistent with some embodiments of this disclosure, the method may also include causing, for each secondary charged-particle beam of the plurality of secondary charged-particle beams, outlier charged particles of the each secondary charged-particle beam to not be detected by the detector. An outlier charged particle of a charged-particle beam, as used herein, may refer to a charged particle belonging to the charged-particle beam and having its distance to a projection axis of a lens being over a predetermined value, or a charged particle belonging to the charged-particle beam and having its signal intensity below a predetermined level. For example, an outlier charged particle may belong to a tail of a cross-section of a secondary-electron beamlet or a secondary-electron spot formed on a detector. In some embodiments, to cause the outlier charged particles to not be detected by the detector, one or more operations may be performed to prevent the outlier charged particles from reaching a surface of the detector, or to cause the detector not to respond (e.g., by using a control signal) to the outlier charged particles if the outlier charged particles reach the surface of the detector.

In some embodiments, to cause the outlier charged particles of the each secondary charged-particle beam to not be detected by the detector, a beam limiting aperture configuration may be adjusted to cause a beam limiting aperture to be positioned upstream to the detector (e.g., upstream to the lens) and to filter the outlier charged particles (e.g., allowing a portion of the plurality of secondary charged-particle beams to pass the beam limiting aperture). A beam limiting aperture configuration in this disclosure may refer to arrangements, combinations, groupings, placements, or any spatial positioning of one or more beam limiting apertures. For example, an aperture plate may include one or more beam limiting apertures (e.g., with different sizes) arranged in a linear manner, a circular manner, a rectangular manner, or any geometric manner. Adjusting a beam limiting aperture configuration, as used herein, may refer to moving, rotating, switching, inserting, adding, activating, or any operation of change positioning of the one or more beam limiting apertures in the beam limiting aperture configuration. For example, if an aperture plate includes multiple beam limiting apertures that have different sizes, the aperture plate may be moved (e.g., linearly) or rotated to switch between the one or more beam limiting apertures to render one beam limiting aperture of the beam limiting aperture configuration to be functional (e.g., by positioning the beam limiting aperture on a projection axis of the lens). In some embodiments, in a scenario where no beam limiting aperture is positioned upstream to the detector (e.g., upstream to the lens), the beam limiting aperture configuration may be adjusted by inserting (e.g., moved by a mechanic activator) an aperture plate that includes one or more beam limiting apertures to position a beam limiting aperture of the aperture plate on a projection axis of the lens (e.g., upstream to the detector or upstream to the lens) such that the beam limiting aperture filters the plurality of secondary charged-particle beams. In some embodiments, in a scenario where an aperture plate that has one or more beam limiting apertures of different sizes has been positioned on a projection axis of the lens such that a first beam limiting aperture of a first size is positioned upstream to the detector (e.g., upstream to the lens), the beam limiting aperture configuration may be adjusted by switching (e.g., by moving or rotating the aperture plate) from the first beam limiting aperture to a second beam limiting aperture of a second size such that the second beam limiting aperture is positioned upstream to the detector (e.g., upstream to the lens). The second beam limiting aperture may then filter the plurality of secondary charged-particle beams. In some embodiments, a controller (e.g., controller 109 in FIG. 2) may adjust the beam limiting aperture configuration in response to receiving an input signal (e.g., from a graphical user interface communicatively coupled to the controller). For example, the graphical user interface may be implemented on a computer and be configured to receive input data (e.g., data of instructing to enable the beam limiting aperture) from an operator (e.g., an individual). In some embodiments, the controller may monitor a predetermined condition (e.g., a timing condition or the like) and automatically (e.g., without human operation or intervention) adjust the beam limiting aperture configuration if the predetermined condition is met.

By way of example, with reference back to FIG. 3, beam limiting aperture 304 may be enabled to filter multiple secondary beamlets (including secondary beamlets 236, 238, and 240). In such a case, one or more of the multiple secondary beamlets may pass beam limiting aperture 304.

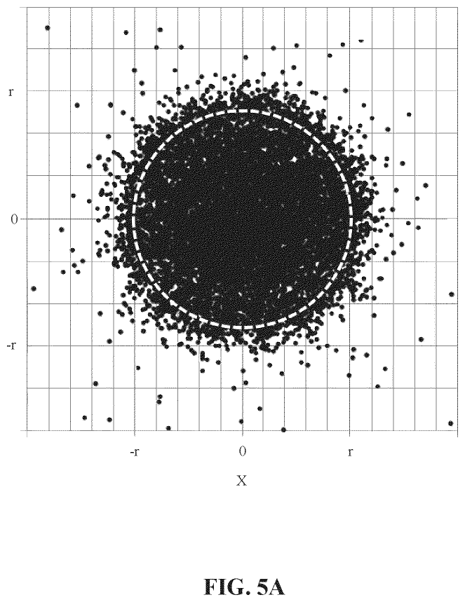

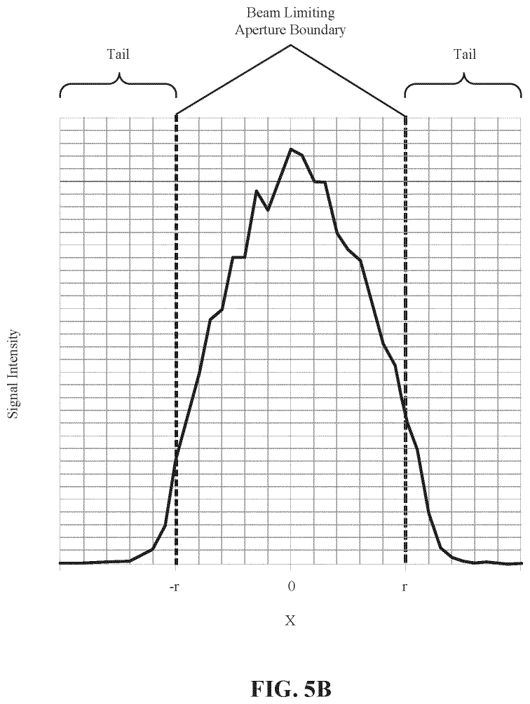

FIG. 5A is a graph visualizing a cross-section of an example charged-particle beam on a plane of a beam limiting aperture, consistent with some embodiments of the present disclosure. The beam limiting aperture may be positioned along a projection path of the charged-particle beam before a detector plane. For example, the beam limiting aperture may be beam limiting aperture 304 as illustrated and described in association with FIG. 3.

As illustrated in FIG. 5A, the charged-particle beam is represented by a group of black dots in which each black dot may represent a charged-particle ray belonging to the charged-particle beam. The contour of the beam aperture is represented by a white-dashed circle in FIG. 5A. The X-and Y-axis in FIG. 5A are on the plane of the beam limiting aperture and illustrated with arbitrary units. The center of the cross-section of the charged-particle beam is at a coordinate (0, 0), as shown in FIG. 5A. The beam limiting aperture is positioned in a manner that the center of the beam limiting aperture is also positioned at the coordinate (0, 0). The radius of the beam limiting aperture is r (r being a number with an arbitrary unit).

With reference to FIG. 5A, when the beam limiting aperture is enabled, charged particles in charged-particle rays outside the beam limiting aperture (i.e., represented by the white-dashed circle) may be the outlier charged particles and may be filtered by the beam limiting aperture such that the charged-particle rays outside the beam limiting aperture may not reach the detector, and thus the outlier charged particles may not be detected by the detector. In comparison, charged-particle rays inside the beam limiting aperture may pass through the beam limiting aperture and reach the detector to be detected.

As illustrated FIG. 5A, the charged-particle rays outside the beam limiting aperture may be marginal rays (e.g., marginal rays 414 illustrated in FIGS. 4A-4B). FIG. 5B is a graph illustrating a profile of the example charged-particle beam of FIG. 5A, consistent with some embodiments of the present disclosure. The X-axis in FIG. 5B are the same as the X-axis in FIG. 5A. The Y-axis in FIG. 5B represents detector signal intensities (e.g., representing a count of detected charged particles). The center of the charged-particle beam is at position 0 of the X-axis, as shown in FIG. 5B. The beam limiting aperture is positioned in a manner that the center of the beam limiting aperture is also positioned at position 0 of the X-axis. The radius of the beam limiting aperture is r, and the boundary of the beam aperture is represented by two vertical dashed lines at positions of +r and −r on the X-axis. As illustrated FIG. 5B, when the beam limiting aperture is enabled, the tail of the beam spot may be cut off (e.g., blocked or filtered) by the beam limiting aperture, and only the central portion of the charged-particle beam may pass through the beam limiting aperture and reach the detector to be detected.

In some embodiments, when the detector is a pixelated detector, to cause the outlier charged particles of the each secondary charged-particle beam to not be detected by the detector, the method may include selecting a subset of pixels from pixels covered by the each secondary charged-particle beam. For example, the pixels covered by a secondary charged-particle beam may include pixels of a detector cell. The detection results of pixels of the detector cell outside the subset may be ignored. For example, in a scenario where no beam limiting aperture is enabled, outlier charged particles of a secondary charged-particle beam may land on pixels of the pixelated detector and contribute to the size of the beam spot (e.g., forming the outer part of the beam spot). A center of the beam spot may be determined, and a subset of pixels may be selected based on a predetermined radius (e.g., the subset being particular pixels inside the predetermined radius). Based on the subset of the pixels, for any pixels responding to the beam spot and being located outside the subset, their detection results may be ignored.

As another example, in a scenario where a beam limiting aperture is enabled as described herein, the above-described operation may be additionally performed to further filter any outlier charged-particles not filtered by the beam limiting aperture.

Consistent with some embodiments of this disclosure, the method may further include refocusing the lens to adjust (e.g., to maximize) currents of a portion of the plurality of secondary charged-particle beams detected by the detector. The outlier charged particles do not contribute to the currents. Refocusing a lens, as used herein, may refer to any operation to adjust (e.g., increase, decrease, or maintain) a focusing power (e.g., a refractive power) of the lens after the focusing power has been set. For example, if the lens is an electromagnetic lens, and if the focusing power of the electromagnetic lens has been set in a previous operation, excitations of the electromagnetic lens may be adjusted to increase, decrease, or maintain its focusing power.

A current of a beam, as used herein, may refer to an electric current of a charged-particle beam. A current of a beam may represent a total charge carried by charged particles of the charged-particle beam that passes a detector plane in a unit time interval (e.g., in one second) and recorded by the detector. In this disclosure, a contribution of a charged particle to a current of a beam refers to a charge carried by the charged particle that passes a detector plane and recorded by the detector. In some embodiments, if a charged particle belongs to a charged-particle beam but does not reach the surface of the detector (e.g., being filtered by a beam limiting aperture), the charged particle does not contribute to the current of the charged-particle beam. In some embodiments, if the detector is a pixelated detector, and if a charged particle belongs to a charged-particle beam and reaches a pixel of the pixelated detector but is not recorded by the detector (e.g., a detection result of the pixel being ignored), the charged particle does not contribute to the current of the charged-particle beam.

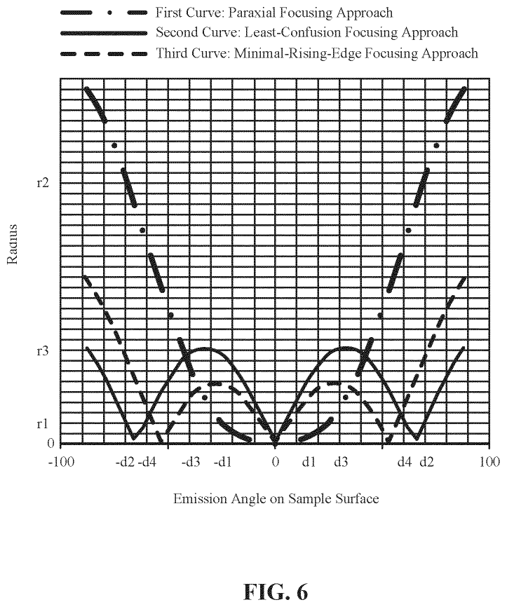

FIG. 6 is a graph illustrating example beam spot size optimization using different beam focusing approaches, consistent with some embodiments of the present disclosure. In FIG. 6, the X-axis represents emission angles measured at a surface of a sample (e.g., sample 230 illustrated in FIG. 2) with a unit of degree. An emission angle, as used herein, refers to an angle between a trajectory of a secondary charged particle and a normal of a surface of a sample. The Y-axis in FIG. 6 represents radii of secondary beam spots measured on the detector plane with an arbitrary unit. Each curve in FIG. 6 may represent a change of a radius (e.g., an offset or distance measured from a projection axis) of a secondary beam spot in response to a change of an emission angle of a secondary charged-particle beam that forms the secondary beam spot. Different curves in FIG. 6 illustrate different secondary beam spot sizes achievable under different beam focusing approaches.

FIG. 6 depicts three curves that correspond to three beam focusing approaches. In FIG. 6, a first curve (represented by a dot-dash curve) corresponds to a paraxial focusing approach, a second curve (represented by a solid-line curve) corresponds to a least-confusion focusing approach, and a third curve (represented by a dashed curve) corresponds to a minimal-rising-edge focusing approach. As illustrated by the first curve in FIG. 6, the radius of a secondary beam spot (e.g., formed by paraxial rays) is small (e.g., under r1, r1 being a number with an arbitrary unit) when its corresponding emission angle is substantially zero (e.g., not exceeding d1, d1 being a number with a unit of degree). As the emission angle increases, the radius of the secondary beam spot may increase quickly. When its corresponding emission angle is large (e.g., over d2, d2 being a number with a unit of degree), the radius of the secondary beam spot (e.g., formed by marginal rays) may be very large (e.g., over r2, r2 being a number with the arbitrary unit).

As illustrated by the second curve in FIG. 6, the maximum radius of the marginal rays projected on the detector plane is r3 (r3 being a number with the arbitrary unit) corresponding to the emission angle of d2, and the maximum radius of the paraxial rays projected on the detector plane is also r3 (corresponding to emission angles between d1 and d3, d3 being a number with a unit of degree).

In a case where no outlier charged particle of any secondary charged-particle beam is filtered (e.g., either by a beam limiting aperture or by deactivating detector pixels as described herein), the second curve in FIG. 6 shows that the least-confusion focusing approach may yield the smallest maximum radius (e.g., not exceeding r3) of a secondary beam spot on the detector plane.

As illustrated by the third curve in FIG. 6, for emission angles below d4 (d4 being a number

with a unit of degree), the maximum radius of the paraxial rays projected on the detector plane under the minimal-rising-edge focusing approach is smaller than the maximum radius of the paraxial rays under either the paraxial focusing approach or the least-confusion focusing approach. However, for emission angles above or equal to d4, the maximum radius of the paraxial rays projected on the detector plane under the minimal-rising-edge focusing approach is larger than the maximum radius of the paraxial rays under the least-confusion focusing approach and is smaller than the maximum radius of the paraxial rays under the paraxial focusing approach.

As can be seen from FIG. 6, there is no beam focusing approach that constantly yield the smallest maximum radius of a secondary beam spot on the detector plane. Rather, the smallest maximum radius of the secondary beam spot may depend on various factors, such as one or more emission angles of the secondary charged-particle beam. In some embodiments, when outlier charged particles of the secondary charged-particle beam is caused to not be detected by the detector (e.g., by enabling a beam limiting aperture or limiting a detector cell size of a pixelated detector), a tail of the secondary beam spot may be cut, and only a portion of the secondary beam spot contributes to the final detection signal. In such situations, the smallest maximum radius of the secondary beam spot may also depend on which portion of the secondary beam spot contributes to the final detection signal. In some embodiments, a selected beam focusing approach may emphasize to focus a central part of a secondary charged-particle beam and relax requirements imposed on focusing a marginal part of the secondary charged-particle beam.

In some embodiments, the method may include focusing the lens to adjust sizes of the secondary beam spots using a first beam focusing approach (e.g., one of a paraxial focusing approach, a least-confusion focusing approach, or a minimal-rising-edge focusing approach). The method may include causing the outlier charged particles of the secondary charged-particle beam to not be detected by the detector (e.g., when a beam-limiting aperture is enabled). The method may also include refocusing the lens to adjust the currents of the portion of the plurality of secondary charged-particle beams detected by the detector using a second beam focusing approach (e.g., one of the paraxial focusing approach, the least-confusion focusing approach, or the minimal-rising-edge focusing approach) that is different from the first beam focusing approach. For example, the first beam focusing approach may be a least-confusion focusing approach, and the second focusing approach may be a paraxial focusing approach.

In some embodiments, to refocus the lens to adjust the currents, the method may include refocusing the lens to cause a focal point of the lens to move towards (or away from) a plane of the detector for a first step distance. The method may also include determining whether a value of the collection efficiency increases and whether a value of a crosstalk ratio is below a predetermined threshold. The method may further include, based on a determination that the value of the collection efficiency increases and a determination that the value of the crosstalk ratio is below the predetermined threshold, refocusing the lens to cause the focal point of the lens to move towards (or away from) a plane of the detector for a second step distance. In some embodiments, based on a determination that value of the collection efficiency decreases, the method may further include changing a scanning direction of the multi-beam inspection apparatus.

By way of example, the lens may be focused to adjust sizes of the secondary beam spots using a least-confusion focusing approach, and outlier charged particles of each secondary charged-particle beam may not be detected by the detector (e.g., by enabling a beam limiting aperture or limiting a detector cell size of a pixelated detector). At this stage, because the ellipse of least confusion is placed on the detector plane, the focal point of the lens may be behind the detector plane along the projection direction. After that, the lens may be refocused using an approach different from the least-confusion focusing approach.

For example, the lens may be refocused using a paraxial focusing approach. In such an example, the focusing power (e.g., a refraction power) of the lens may be adjusted (e.g., increased) to move the focal point of the lens to move towards or away from the detector plane for a first step distance. After moving the focal point for the first step distance, the focus point may still be behind the detector plane along the projection direction. At this stage, whether a value of the collection efficiency increases may be determined, and whether a value of a crosstalk ratio is below a predetermined threshold may also be determined. If the value of the collection efficiency increases and if the value of the crosstalk ratio is below the predetermined threshold, the focusing power of the lens may be further adjusted (e.g., further increased) to move the focal point of the lens to move towards or away from the detector plane for a second step distance. The first step distance may be the same as or different from the second step distance.

As another example, the lens may be refocused using a minimal-step-edge focusing approach. In such an example, the focusing power (e.g., a refraction power) of the lens may be adjusted (e.g., increased or decreased) to reduce a rising-edge width of a secondary beam spot for a first value. After reducing the rising-edge width, whether a value of the collection efficiency increases may be determined, and whether a value of a crosstalk ratio is below a predetermined threshold may also be determined. If the value of the collection efficiency increases and if the value of the crosstalk ratio is below the predetermined threshold, the focusing power of the lens may be further adjusted (e.g., further increased or further decreased) to reduce the rising-edge width for a second value. The first value may be the same as or different from the second value.

In some embodiments, after refocusing the lens to adjust the currents, the method may further include, based on a determination that the value of the collection efficiency reaches a maximum value or a determination that the value of the crosstalk ratio is not below the predetermined threshold, stopping refocusing the lens.

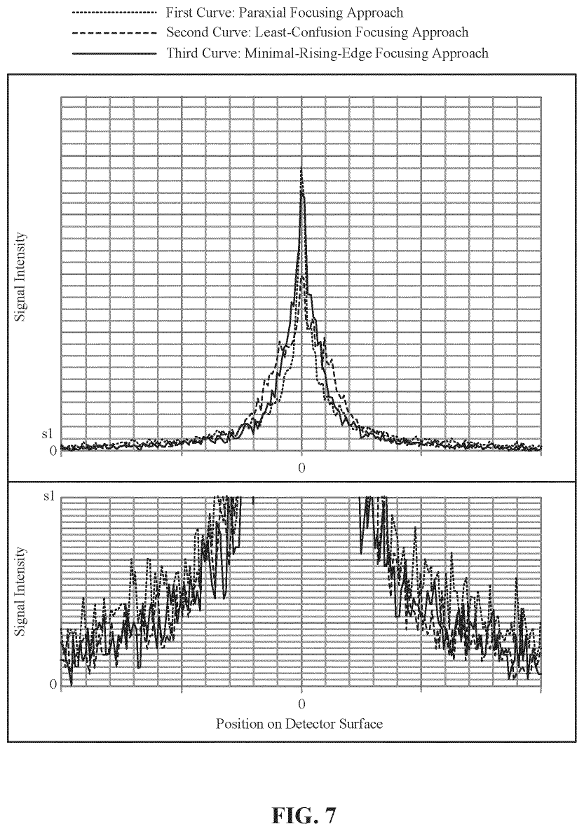

In some embodiments, when the detector is a pixelated detector, the lens may be refocused to adjust the currents depending on a detector cell size of the pixelated detector. By way of example, FIG. 7 is a graph illustrating example signal intensity distributions of secondary beam spots corresponding to different beam focusing approaches, consistent with some embodiments of the present disclosure. In FIG. 7, the X-axis represents a spatial position with an arbitrary unit on a detector surface. The position 0 at the X-axis may represent a center of a secondary beam spot. The Y-axis in FIG. 7 represents a signal intensity value (e.g., representing a count of charged particles) with an arbitrary unit at a corresponding spatial position. FIG. 7 includes a top sub-graph and a bottom sub-graph stacked vertically, in which the bottom sub-graph is a blown-up view of the lower portion (e.g., the portion of signal intensities from 0 to s1, s1 being a number with an arbitrary unit) of the top sub-graph and share the same X-axis with the top sub-graph. Each curve in FIG. 7 may represent a distribution of signal intensities of a secondary beam spot along a direction represented by the X-axis.

FIG. 7 depicts three curves that correspond to three beam focusing approaches. In FIG. 7, a first curve (represented by a dotted curve) corresponds to a paraxial focusing approach, a second curve (represented by a dashed curve) corresponds to a least-confusion focusing approach, and a third curve (represented by a solid-line curve) corresponds to a minimal-rising-edge focusing approach. As illustrated by the three curves in FIG. 7, the first curve has the highest intensity at position 0, the smallest full width at half maximum (FWHM), and the largest beam-spot tail (e.g., represented by the highest signal intensities at positions far away from position 0). The second curve has the lowest intensity at position 0, the largest FWHM, and the smallest beam-spot tail (e.g., represented by the lowest signal intensities at positions far away from position 0). The third curve has an intermediate intensity at position 0, an intermediate FWHM, and an intermediate beam-spot tail. As shown by FIG. 7, depending on detector cell sizes, optimized secondary beam focusing (e.g., represented by the highest intensity at beam spot center, the smallest FWHW, or the smallest beam-spot tail) is not constantly generated by the same beam focusing approach.

In some embodiments, when the detector is a pixelated detector, to refocus the lens to adjust the currents, the method may include, based on a detector cell size (e.g., a size of a group of pixels) of the pixelated detector, refocusing the lens to adjust the currents of the portion of the plurality of secondary charged-particle beams detected by the detector. For example, the lens may be refocused using a beam focusing approach (e.g., a paraxial focusing approach or a minimal-rising-edge focusing approach) different from the beam focusing approach (e.g., a least-confusion focusing approach) used for focusing the lens to adjust the sizes of the secondary beam spots, in which the detector cell size may be a factor for determining which beam focusing approach to use for refocusing the lens.

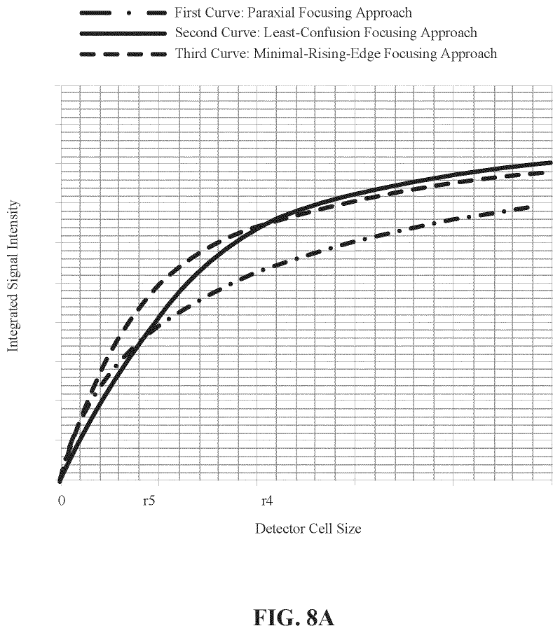

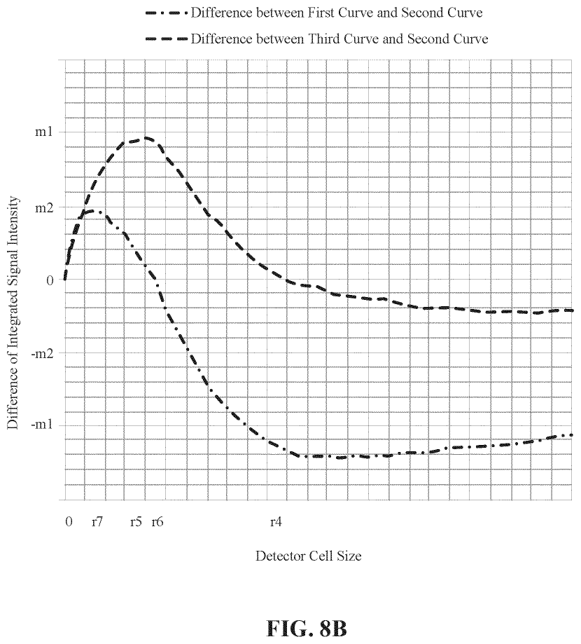

By way of example, FIG. 8A is a graph illustrating example integrated signal intensities of secondary beam spots corresponding to different beam focusing approaches, consistent with some embodiments of the present disclosure. In FIG. 8A, the X-axis represents a radius of a detector cell size (e.g., a detector cell radius) with an arbitrary unit. The Y-axis in FIG. 8A represents an integrated signal intensity value (e.g., representing a total count of charged particles within the detector cell) with an arbitrary unit corresponding to a detector cell size. Each curve in FIG. 8A may represent integrated signal intensities of a secondary beam spot as a function of the detector cell size. The curves in FIG. 8A illustrates that the integrated signal intensity increases as the detector cell size increases.

FIG. 8A depicts three curves that correspond to three beam focusing approaches. In FIG. 8A, a first curve (represented by a dot-dash curve) corresponds to a paraxial focusing approach, a second curve (represented by a solid-line curve) corresponds to a least-confusion focusing approach, and a third curve (represented by a dashed curve) corresponds to a minimal-rising-edge focusing approach. As illustrated by the three curves in FIG. 8A, the second curve has the highest integrated intensity values for large detector cells (e.g., with a detector cell size over r4, r4 being a number with an arbitrary unit), and the third curve has the highest integrated intensity values for small detector cells (e.g., with a detector cell size under r4). Also, for detector cells with a size under r5 (r5 being a number with an arbitrary unit), integrated intensity values of the first curve are higher than integrated intensity values of the second curve. As shown by FIG. 8A, depending on detector cell sizes, optimized secondary beam focusing (e.g., represented by the highest integrated intensity value) is not constantly generated by the same beam focusing approach.

FIG. 8B is a graph illustrating differences between example integrated signal intensities of secondary beam spots corresponding to different beam focusing approaches, consistent with some embodiments of the present disclosure. Similar to FIG. 8A, the X-axis in FIG. 8B represents a radius of a detector cell size with an arbitrary unit. The Y-axis in FIG. 8B represents a difference value between two integrated signal intensity values with an arbitrary unit corresponding to a detector cell size.

FIG. 8B depicts two curves. In FIG. 8B, a first difference curve (represented by a dot-dash curve) represents difference values between the first curve and the second curve illustrated and described in FIG. 8A, and a second difference curve (represented by a dashed curve) represents difference values between the third curve and the second curve illustrated and described in FIG. 8A. As illustrated in FIG. 8B, the first difference curve is positive for detector cell sizes under r4 with a maximum value of m1 (e.g., at a detector cell size of r5), in which ml is a number with an arbitrary unit. The second difference curve is positive for detector cell sizes under r6 (r6 being a number with an arbitrary unit) with a maximum value of m2 (e.g., at a detector cell size of r7, r7 being a number with an arbitrary unit), in which m2 is a number with an arbitrary unit. As shown by FIG. 8B, a switch from a least-confusion focusing approach to either a paraxial focusing approach or minimal-rising-edge focusing approach may gain an increase of m2 to m1 for the maximum integrated signal intensity if the detector cell size is set to specific values.

By way of example, with reference to FIGS. 8A-8B, when the detector is a pixelated detector, a least-confusion focusing approach may be used for focusing the lens to adjust (e.g., to minimize) the sizes of the secondary beam spots. After that, if the detector cell size of the pixelated detector is over r4, no refocusing may be performed for the lens because the currents are maximized in such a case. If the detector cell size is between r5 and r4, to refocus the lens to adjust the currents, the lens may be refocused using a minimal-rising-edge focusing approach. If the detector cell size is smaller than r5, the lens may be refocused using either the minimal-rising-edge focusing approach or a paraxial focusing approach.

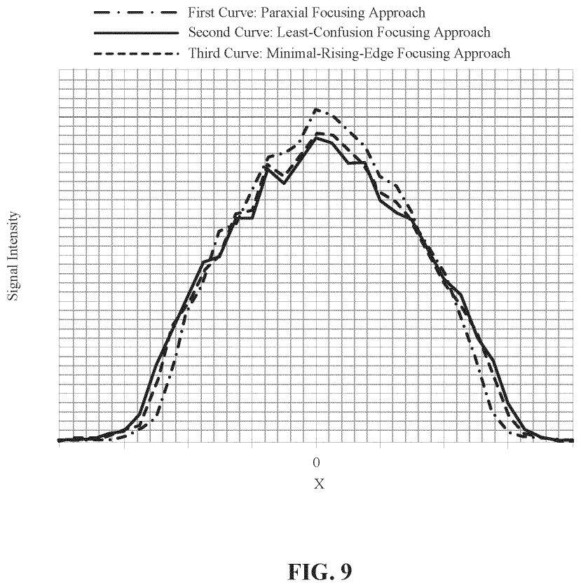

In some embodiments, if a beam limiting aperture is enabled, the lens may be refocused to adjust the currents depending on an aperture size of the beam limiting aperture. By way of example, FIG. 9 is a graph illustrating profiles (represented by curves) of example secondary beam spots on a plane of a beam limiting aperture corresponding to different beam focusing approaches, consistent with some embodiments of the present disclosure. In FIG. 9, the X-axis represents a spatial position with an arbitrary unit on the plane of the beam limiting aperture (e.g., similar to the beam limiting aperture described in association of FIGS. 5A-5B). The position 0 at the X-axis may represent a center of a secondary beam spot. The Y-axis in FIG. 9 represents a signal intensity value (e.g., representing a count of charged particles) with an arbitrary unit at a corresponding spatial position. Each curve in FIG. 9 may represent a distribution of signal intensities of a secondary beam spot along a direction represented by the X-axis.

FIG. 9 depicts three curves that correspond to three beam focusing approaches. In FIG. 9, a first curve (represented by a dot-dash curve) corresponds to a paraxial focusing approach, a second curve (represented by a solid-line curve) corresponds to a least-confusion focusing approach, and a third curve (represented by a dashed curve) corresponds to a minimal-rising-edge focusing approach. As illustrated by the three curves in FIG. 9, the second curve has the largest FWHM, and the first curve has the highest signal intensity at the center of the beam spot.

In some embodiments, to refocus the lens to adjust the currents, the method may include, based on an aperture size (e.g., a radius) of the beam limiting aperture, refocusing the lens to adjust the currents of the plurality of secondary charged-particle beams. For example, the lens may be refocused using a beam focusing approach (e.g., a paraxial focusing approach or a minimal-rising-edge focusing approach) different from the beam focusing approach (e.g., a least-confusion focusing approach) used for focusing the lens to adjust the sizes of the secondary beam spots, in which the aperture size may be a factor for determining which beam focusing approach to use for refocusing the lens.

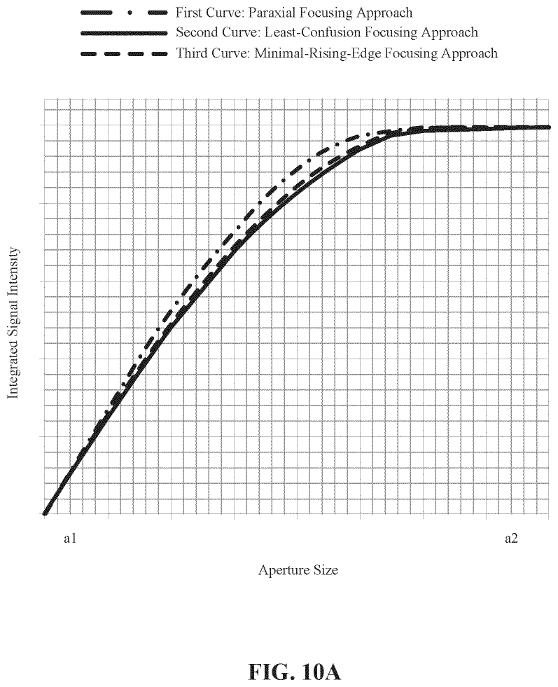

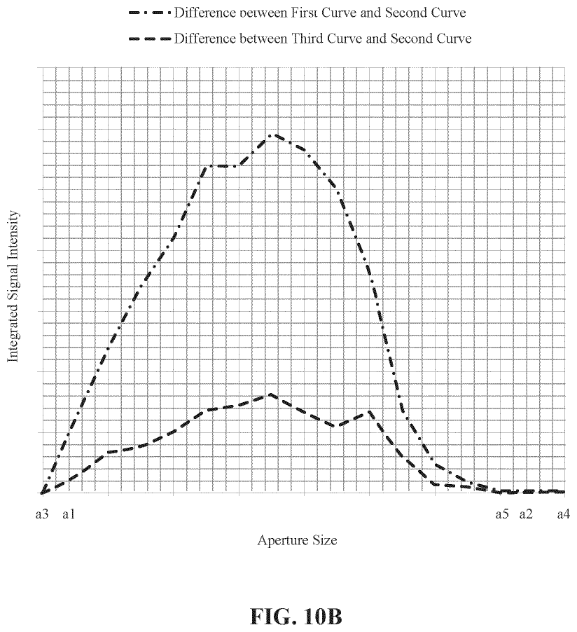

By way of example, FIG. 10A is a graph illustrating example integrated signal intensities of secondary beam spots corresponding to different beam focusing approaches, consistent with some embodiments of the present disclosure. In FIG. 10A, the X-axis represents an aperture size (e.g., an aperture radius) with an arbitrary unit. The Y-axis in FIG. 10A represents an integrated signal intensity value (e.g., representing a total count of charged particles that pass the beam limiting aperture) with an arbitrary unit corresponding to an aperture size. Each curve in FIG. 10A may represent integrated signal intensities of a secondary beam spot as a function of the aperture size. The curves in FIG. 10A illustrates that the integrated signal intensity increases as the aperture size increases.

FIG. 10A depicts three curves that correspond to three beam focusing approaches. In FIG. 10A, a first curve (represented by a dot-dash curve) corresponds to a paraxial focusing approach, a second curve (represented by a solid-line curve) corresponds to a least-confusion focusing approach, and a third curve (represented by a dashed curve) corresponds to a minimal-rising-edge focusing approach. As illustrated by the three curves in FIG. 10A, for a wide range of the aperture sizes (e.g., between sizes of a1 and a2, a1 and a2 being numbers with an arbitrary unit), the integrated signal intensity values of the first curve and the third curve are higher than the integrated signal intensity values of the second curve. As shown by FIG. 10A, depending on aperture sizes, optimized secondary beam focusing (e.g., represented by the highest integrated intensity value) is not constantly generated by the same beam focusing approach.

FIG. 10B is a graph illustrating differences between example integrated signal intensities of secondary beam spots corresponding to different beam focusing approaches, consistent with some embodiments of the present disclosure. Similar to FIG. 10A, the X-axis in FIG. 10B represents an aperture size with an arbitrary unit. The Y-axis in FIG. 10B represents a difference value between two integrated signal intensity values with an arbitrary unit corresponding to an aperture size.

FIG. 10B depicts two curves. In FIG. 10B, a first difference curve (represented by a dot-dash curve) represents difference values between the first curve and the second curve illustrated and described in FIG. 10A, and a second difference curve (represented by a dashed curve) represents difference values between the third curve and the second curve illustrated and described in FIG. 10A. As illustrated in FIG. 10B, both the first difference curve and the second difference curve have positive values in a wide range of aperture sizes (e.g., aperture sizes between a3 and a4, a3 and a4 being numbers with an arbitrary unit). Also, values of the first difference curve are higher than values of the second difference curve in a range of aperture sizes between a3 and a5 (a5 being a number with an arbitrary unit). As shown by FIG. 10B, a switch from a least-confusion focusing approach to either a paraxial focusing approach or minimal-rising-edge focusing approach may gain an increase for the maximum integrated signal intensity if the aperture size is set to specific values.

By way of example, with reference to FIGS. 10A-10B, a least-confusion focusing approach may be used for focusing the lens to adjust the sizes of the secondary beam spots. Then, a beam limiting aperture may be enabled as described herein. After that, if an aperture size of the beam limiting aperture is under a4, the lens may be refocused using either a minimal-rising-edge focusing approach or a paraxial focusing approach. If the aperture size is under a5, to refocus the lens to adjust the currents, the lens may be refocused using the paraxial focusing approach.

It should be noted that, if the detector is a pixelated detector and if a beam limiting aperture is enabled, the lens may be refocused to adjust the currents depending on both a detector cell size and an aperture size of the beam limiting aperture. For example, the lens may be refocused to maximize the currents of the portion of the plurality of secondary charged-particle beams detected by the detector based on both a detector cell size of the pixelated detector and an aperture size of the beam limiting aperture.

In some embodiments, if a beam limiting aperture is enabled, the lens may be refocused to adjust the currents depending on a position of the beam limiting aperture along a projection axis of the lens. For example, to refocus the lens to adjust the currents, the method may include, based on a position of the beam limiting aperture along a projection axis of the lens, refocusing the lens to adjust the currents of the plurality of secondary charged-particle beams.

It should also be noted that, the method of optimizing collection efficiency of secondary charged particles described herein may be applied for a theoretical optimization process (e.g., a simulation process for optimizing performance of the imaging system) or an experimental process (e.g., an actual measurement process). By way of example, in an experimental process, assuming the detector of a multi-beam inspection apparatus is a pixelated detector, the pixelated detector may be switched to work in an imaging mode that may generate images of secondary beam spots. Under the imaging mode, a lens of the multi-beam inspection apparatus may be focused (e.g., using a least-confusion focusing approach) to adjust sizes of the secondary beam spots, in which the secondary beam spots are formed by a plurality of secondary charged-particle beams on a detector. In some embodiments, the lens may be focused without enabling any beam limiting aperture in projection paths of the plurality of secondary charged-particle beams. Then, the pixelated detector may be switched to work in a measurement mode that may generate detection results that include no images of the secondary beam spots. Under the measurement mode, a detector cell (e.g., a group of pixels) may receive a secondary beam spot, and an intensity value of the secondary beam spot may be determined (e.g., by integrating signal values of all pixels in the detector cell). After that, a beam limiting aperture configuration may be adjusted to cause a beam limiting aperture to be positioned upstream to the detector (e.g., upstream to the lens) and to filter the outlier charged particles. By enabling the beam limiting aperture, the crosstalk may be suppressed (e.g., to cause a crosstalk ratio to be below a predetermined threshold). After enabling the beam limiting aperture, the lens may be refocused (e.g., using a paraxial focusing approach or a minimal-rising-edge focusing approach) to adjust the currents of the plurality of secondary charged-particle beams detected by the detector, in which the outlier charged particles do not contribute to the currents. For example, to refocus the lens, the focusing power of the lens may be adjusted (e.g., increased). As another example, to refocus the lens, the focusing power of the lens may be adjusted (e.g., increased or decreased) to reduce a rising-edge width of a secondary beam spot.

It should be further noted that although only three beam focusing approaches (e.g., a paraxial focusing approach, a least-confusion focusing approach, and a minimal-rising-edge focusing approach) are described in this disclosure, they are only example embodiments for illustration purpose only. Other beam focusing approaches are not excluded and may also be used in the embodiments of this disclosure.

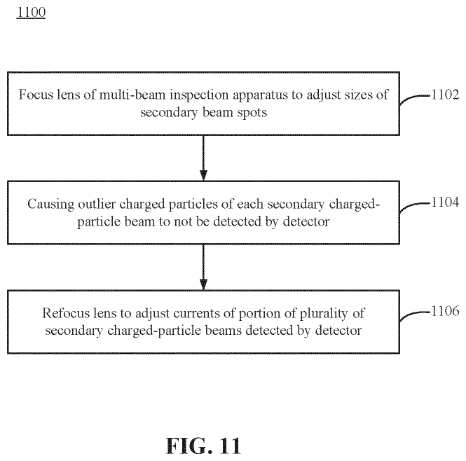

FIG. 11 is a flowchart illustrating an example method of optimizing collection efficiency of secondary charged particles, consistent with some embodiments of the present disclosure. Method 1100 may be performed by a controller that may be coupled with a charged-particle beam inspection apparatus (e.g., beam tool 104 described in association with FIGS. 1-3). For example, the controller may be controller 109 in FIG. 2. The controller may be programmed to implement method 1100.

At step 1102, the controller may focus a lens (e.g., an objective lens in secondary column 300 of FIG. 3) of a multi-beam inspection apparatus (e.g., beam tool 104 of FIG. 2) to adjust sizes of secondary beam spots. The secondary beam spots may be formed by a plurality of secondary charged-particle beams (e.g., including secondary beamlets 236, 238, and 240 of FIG. 3) on a detector (e.g., charged-particle detector 244 of FIG. 3).

In some embodiments, the controller may focus the lens using a first beam focusing method. The first beam focusing method may include one of: focusing the lens to cause paraxial rays of the plurality of secondary charged-particle beams to focus on a plane of the detector; focusing the lens to position ellipses of least confusion of the plurality of secondary charged-particle beams on the plane of the detector to form the secondary beam spots; or focusing the lens to minimize rising-edge widths of the secondary beam spots.

At step 1104, the controller may cause, for each secondary charged-particle beam of the plurality of secondary charged-particle beams, outlier charged particles of the each secondary charged-particle beam to not be detected by the detector. In some embodiments, to cause the outlier charged particles to not be detected by the detector, the controller may adjust a beam limiting aperture configuration to cause a beam limiting aperture (e.g., beam limiting aperture 304 of FIG. 3) to be positioned upstream to the detector (e.g., lens 310 of FIG. 3) and to filter the outlier charged particles. For example, with reference to FIGS. 5A-5B, the beam limiting aperture may block the outlier charged particles of a secondary charged-particle beam (e.g., charged particles in the tail of the secondary beam spot) to prevent them from reaching the detector.

In some embodiments, the detector may be a pixelated detector. In such scenarios, to cause the outlier charged particles not to be detected by the detector, the controller may adjust a number of pixels of a detector cell of the detector, in which the pixels of the detector cell may be used for detecting the plurality of secondary charged-particle beams. For example, a group of pixels (e.g., a detector cell) may receive and detect a secondary charged-particle beam, and the detector may include multiple detector cells. The controller may adjust a number of pixels for each detector cell (e.g., by reducing the number of pixels in the detector cell) for detecting the plurality of secondary charged-particle beams.

In some embodiments, if the detector is a pixelated detector, to cause the outlier charged particles to not be detected by the detector, the controller may select a subset of pixels from pixels covered by the each secondary charged-particle beam. For example, a detector cell (that includes a group of pixels) may receive and detect a secondary charged-particle beam. Pixels of the detector cell may be covered by the secondary charged-particle beam. The controller may obtain a predetermined size of the detector cell and select the subset of pixels based on the predetermined size. For all pixels located outside the subset, the controller may ignore their detection results (e.g., by disabling their function or not processing their signals) even if charged particles of the secondary charged-particle beam land on them.

At step 1106, the controller may refocus the lens to adjust (e.g., to maximize) currents of a portion of the plurality of secondary charged-particle beams detected by the detector. The outlier charged particles do not contribute to the currents. In some embodiments, if the controller has focused the lens using the first beam focusing method described in association with step 1102, the controller may refocus the lens to adjust the currents using a second beam focusing method different from the first beam focusing method. The second beam focusing method may include one of: focusing the lens to cause paraxial rays of the plurality of secondary charged-particle beams to focus on a plane of the detector; focusing the lens to position ellipses of least confusion of the plurality of secondary charged-particle beams on the plane of the detector to form the secondary beam spots; or focusing the lens to minimize rising-edge widths of the secondary beam spots.

In some embodiments, if the controller has enabled the beam limiting aperture described in association with step 1104, to refocus the lens to adjust the currents, based on an aperture size of the beam limiting aperture, the controller may refocus the lens to adjust the currents of the plurality of secondary charged-particle beams detected by the detector. By way of example, based on relationships between integrated signal intensities and aperture sizes as described in association with FIGS. 10A-10B, the controller may select a beam focusing approach to refocus the lens to adjust the currents.

In some embodiments, if the controller has enabled the beam limiting aperture described in association with step 1104, to refocus the lens to adjust the currents, based on a position of the beam limiting aperture along a projection axis (e.g., projection axis 252 in FIGS. 2-3) of the lens, the controller may refocus the lens to adjust the currents of the portion of the plurality of secondary charged-particle beams detected by the detector. By way of example, based on relationships between integrated signal intensities and positions of the beam limiting aperture along the projection axis, the controller may select a beam focusing approach to refocus the lens to adjust the currents.

In some embodiments, if the detector is a pixelated detector, to refocus the lens to adjust the currents, based on a detector cell size of the pixelated detector, the controller may refocus the lens to adjust the currents of the portion of the plurality of secondary charged-particle beams detected by the detector. By way of example, based on relationships between integrated signal intensities and detector cell sizes as described in association with FIGS. 8A-8B, the controller may select a beam focusing approach to refocus the lens to adjust the currents.

In some embodiments, to refocus the lens to adjust the currents, the controller may refocus the lens to cause a focal point (e.g., focal point 408 described in association with FIGS. 4A-4B) of the lens to move towards or away from a plane of the detector for a first step distance. The controller may also determine whether a value of the collection efficiency increases and whether a value of a crosstalk ratio is below a predetermined threshold based on a determination that the value of the collection efficiency increases and a determination that the value of the crosstalk ratio is below the predetermined threshold, the controller may refocus the lens to cause the focal point of the lens to move towards or away from the plane of the detector for a second step distance. The second step distance may be the same as or different from the first step distance. In some embodiments, based on a determination that the value of the collection efficiency decreases, the controller may change a scanning direction of the multi-beam inspection apparatus. In some embodiments, based on a determination that the value of the collection efficiency reaches a maximum value or a determination that the value of the crosstalk ratio is not below the predetermined threshold, the controller may stop refocusing the lens.

A non-transitory computer readable medium may be provided that stores instructions for a processor (for example, processor of controller 109 of FIG. 1) to carry out methods of optimizing collection efficiency of secondary charged particles such as method 1100 of FIG. 11, data processing, database management, graphical display, operations of an image inspection apparatus or another imaging device, detecting a defect on a sample, or the like. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same.

The embodiments may further be described using the following clauses:

1. A system, comprising:
a multi-beam inspection apparatus configured to scan a sample and comprising a lens; a detector configured to receive a plurality of secondary charged-particle beams in response to scanning the sample; and
a controller including circuitry communicatively coupled to the multi-beam inspection apparatus and the detector, the controller configured to:
focus the lens to adjust sizes of secondary beam spots, wherein the secondary beam spots are formed by the plurality of secondary charged-particle beams on the detector;
cause, for each secondary charged-particle beam of the plurality of secondary charged-particle beams, outlier charged particles of the each secondary charged-particle beam to not be detected by the detector; and
refocus the lens to adjust currents of a portion of the plurality of secondary charged-particle beams detected by the detector, wherein the outlier charged particles do not contribute to the currents.
   2. The system of clause 1, wherein the controller is configured to focus the lens to adjust the sizes of the secondary beam spots to enable minimizing the sizes of the secondary beam spots.
   3. The system of any of clauses 1-2, wherein the controller is configured to refocus the lens to adjust the currents to enable maximizing the currents.
   4. The system of any of clauses 1-3, wherein the detector is a pixelated detector, and the controller is configured to cause the outlier charged particles of the each secondary charged-particle beam to not be detected by adjusting a number of pixels of a detector cell of the detector, wherein the pixels of the detector cell are configured to detect the plurality of secondary charged-particle beams.
   5. The system of any of clauses 1-4, wherein the controller is configured to focus the lens to adjust the sizes of the secondary beam spots using a first beam focusing method, and the first beam focusing method comprises one of:
focusing of the lens to cause paraxial rays of the plurality of secondary charged-particle beams to focus on a plane of the detector;
focusing of the lens to position ellipses of least confusion of the plurality of secondary charged-particle beams on the plane of the detector to form the secondary beam spots; or
focusing of the lens to minimize rising-edge widths of the secondary beam spots.
   6. The system of clause 5, wherein the controller is configured to refocus the lens to adjust the currents using a second beam focusing method different from the first beam focusing method, and the second beam focusing method comprises one of:
focusing of the lens to cause the paraxial rays of the plurality of secondary charged-particle beams to focus on the plane of the detector;
focusing of the lens to position the ellipses of least confusion of the plurality of secondary charged-particle beams on the plane of the detector to form the secondary beam spots; or
focusing of the lens to minimize the rising-edge widths of the secondary beam spots.
   7. The system of any of clauses 1-6, wherein the controller is configured to cause the outlier charged particles of the each secondary charged-particle beam to not be detected by the detector by adjusting a beam limiting aperture configuration to cause a beam limiting aperture of the beam limiting aperture configuration to be positioned upstream to the detector and to filter the outlier charged particles.
   8. The system of clause 7, wherein the controller is configured to cause the outlier charged particles of the each secondary charged-particle beam to not be detected by the detector by adjusting the beam limiting aperture configuration to cause the beam limiting aperture of the beam limiting aperture configuration to be positioned upstream to the lens and to filter the outlier charged particles.
   9. The system of any of clauses 7-8, wherein the controller is configured to refocus the lens to adjust the currents to enable, based on an aperture size of the beam limiting aperture, refocusing of the lens to adjust the currents.
   10. The system of any of clauses 7-9, wherein the controller is configured to refocus the lens to adjust the currents to enable, based on a position of the beam limiting aperture along a projection axis of the lens, refocusing of the lens to adjust the currents.
   11. The system of any of clauses 1-10, wherein the detector is a pixelated detector, and the controller is configured to cause the outlier charged particles of the each secondary charged-particle beam to not be detected by the detector by selecting a subset of pixels from pixels covered by the each secondary charged-particle beam.
   12. The system of any of clauses 1-11, wherein the detector is a pixelated detector, and the controller is configured to refocus the lens to adjust the currents to enable, based on a detector cell size of the pixelated detector, refocusing of the lens to adjust the currents.
   13. The system of any of clauses 1-12, wherein the controller is configured to refocus the lens to adjust the currents to enable refocusing of the lens to cause a focal point of the lens to move towards or away from a plane of the detector for a first step distance;
determine whether a value of the collection efficiency increases and whether a value of a crosstalk ratio is below a predetermined threshold;
based on a determination that the value of the collection efficiency increases and a determination that the value of the crosstalk ratio is below the predetermined threshold, refocus the lens to cause the focal point of the lens to move towards or away from the plane of the detector for a second step distance;
based on a determination that the value of the collection efficiency decreases, changing a scanning direction of the multi-beam inspection apparatus; and
based on a determination that the value of the collection efficiency reaches a maximum value or a determination that the value of the crosstalk ratio is not below the predetermined threshold, stop refocusing the lens.
   14. A non-transitory computer-readable medium that stores a set of instructions that is executable by at least one processor of a multi-beam inspection apparatus to cause the multi-beam inspection apparatus to perform a method, the method comprising:
focusing a lens of the multi-beam inspection apparatus to adjust sizes of secondary beam spots, wherein the secondary beam spots are formed by a plurality of secondary charged-particle beams on a detector; causing, for each secondary charged-particle beam of the plurality of secondary charged-particle beams, outlier charged particles of the each secondary charged-particle beam to not be detected by the detector; and
refocusing the lens to adjust currents of a portion of the plurality of secondary charged-particle beams detected by the detector, wherein the outlier charged particles do not contribute to the currents.
   15. The non-transitory computer-readable medium of clause 14, wherein focusing the lens of the multi-beam inspection apparatus to adjust the sizes of the secondary beam spots comprises:
minimizing the sizes of the secondary beam spots.
   16. The non-transitory computer-readable medium of any of clauses 14-15, wherein refocusing the lens to adjust the currents comprises:
maximizing the currents of the portion of the plurality of secondary charged-particle beams detected by the detector.
   17. The non-transitory computer-readable medium of any of clauses 14-16, wherein the detector is a pixelated detector, and wherein causing the outlier charged particles of the each secondary charged-particle beam to not be detected by the detector comprises:
adjusting a number of pixels of a detector cell of the detector, wherein the pixels of the detector cell are configured to detect the plurality of secondary charged-particle beams.
   18. The non-transitory computer-readable medium of any of clauses 14-17, wherein focusing the lens of the multi-beam inspection apparatus to adjust the sizes of the secondary beam spots comprises a first beam focusing method, and the first beam focusing method comprises one of:
focusing the lens to cause paraxial rays of the plurality of secondary charged-particle beams to focus on a plane of the detector;
focusing the lens to position ellipses of least confusion of the plurality of secondary charged-particle beams on the plane of the detector to form the secondary beam spots; or
focusing the lens to minimize rising-edge widths of the secondary beam spots.
   19. The non-transitory computer-readable medium of any of clauses 14-17, wherein refocusing the lens to adjust the currents comprises a second beam focusing method different from the first beam focusing method, and the second beam focusing method comprises one of:
focusing the lens to cause the paraxial rays of the plurality of secondary charged-particle beams on a plane of the detector;
focusing the lens to position the ellipses of least confusion of the plurality of secondary charged-particle beams on the plane of the detector to form the secondary beam spots; or
focusing the lens to minimize the rising-edge widths of the secondary beam spots.
   20. The non-transitory computer-readable medium of any of clauses 14-19, wherein causing the outlier charged particles of the each secondary charged-particle beam to not be detected by the detector comprises:
adjusting a beam limiting aperture configuration to cause a beam limiting aperture of the beam limiting aperture configuration to be positioned upstream to the detector and to filter the outlier charged particles.
   21. The non-transitory computer-readable medium of clause 20, wherein adjusting the beam limiting aperture configuration comprises:
adjusting the beam limiting aperture configuration to cause the beam limiting aperture of the beam limiting aperture configuration to be positioned upstream to the lens and to filter the outlier charged particles.
   22. The non-transitory computer-readable medium of any of clauses 20-21, wherein refocusing the lens to adjust the currents the detector comprises:
based on an aperture size of the beam limiting aperture, refocusing the lens to adjust the currents.
   23. The non-transitory computer-readable medium of any of clauses 20-22, wherein refocusing the lens to adjust the currents comprises:
based on a position of the beam limiting aperture along a projection axis of the lens, refocusing the lens to adjust the currents.
   24. The non-transitory computer-readable medium of any of clauses 14-23, wherein the detector is a pixelated detector, and wherein causing the outlier charged particles of the each secondary charged-particle beam to not be detected by the detector comprises:
selecting a subset of pixels from pixels covered by the each secondary charged-particle beam.
   25. The non-transitory computer-readable medium of any of clauses 14-24, wherein the detector is a pixelated detector, and wherein refocusing the lens to adjust the currents comprises:
based on a detector cell size of the pixelated detector, refocusing the lens to adjust the currents.
   26. The non-transitory computer-readable medium of any of clauses 14-25, wherein refocusing the lens to adjust the currents comprises:
refocusing the lens to cause a focal point of the lens to move towards or away from a plane of the detector for a first step distance;
determining whether a value of the collection efficiency increases and whether a value of a crosstalk ratio is below a predetermined threshold;
based on a determination that the value of the collection efficiency increases and a determination that the value of the crosstalk ratio is below the predetermined threshold, refocusing the lens to cause the focal point of the lens to move towards or away from the plane of the detector for a second step distance;
based on a determination that the value of the collection efficiency decreases, changing a scanning direction of the multi-beam inspection apparatus; and
based on a determination that the value of the collection efficiency reaches a maximum value or a determination that the value of the crosstalk ratio is not below the predetermined threshold, stopping refocusing the lens.
   27. A method of optimizing collection efficiency of secondary charged particles, comprising: focusing a lens of a multi-beam inspection apparatus to adjust sizes of secondary beam spots, wherein the secondary beam spots are formed by a plurality of secondary charged-particle beams on a detector; causing, for each secondary charged-particle beam of the plurality of secondary charged-particle beams, outlier charged particles of the each secondary charged-particle beam to not be detected by the detector; and
refocusing the lens to adjust currents of a portion of the plurality of secondary charged-particle beams detected by the detector, wherein the outlier charged particles do not contribute to the currents.
   28. The method of clause 27, wherein focusing the lens of the multi-beam inspection apparatus to adjust the sizes of the secondary beam spots comprises:
minimizing the sizes of the secondary beam spots.
   29. The method of any of clauses 27-28, wherein refocusing the lens to adjust the currents comprises:
maximizing the currents of the portion of the plurality of secondary charged-particle beams detected by the detector.
   30. The method of any of clauses 27-29, wherein the detector is a pixelated detector, and wherein causing the outlier charged particles of the each secondary charged-particle beam to not be detected by the detector comprises:
adjusting a number of pixels of a detector cell of the detector, wherein the pixels of the detector cell are configured to detect the plurality of secondary charged-particle beams.
   31. The method of any of clauses 27-30, wherein focusing the lens of the multi-beam inspection apparatus to adjust the sizes of the secondary beam spots comprises a first beam focusing method, and the first beam focusing method comprises one of:
focusing the lens to cause paraxial rays of the plurality of secondary charged-particle beams to focus on a plane of the detector;
focusing the lens to position ellipses of least confusion of the plurality of secondary charged-particle beams on the plane of the detector to form the secondary beam spots; or
focusing the lens to minimize rising-edge widths of the secondary beam spots.
   32. The method of any of clauses 27-31, wherein refocusing the lens to adjust the currents comprises a second beam focusing method different from the first beam focusing method, and the second beam focusing method comprises one of:
focusing the lens to cause the paraxial rays of the plurality of secondary charged-particle beams to focus on a plane of the detector;
focusing the lens to position the ellipses of least confusion of the plurality of secondary charged-particle beams on the plane of the detector to form the secondary beam spots; or
focusing the lens to minimize the rising-edge widths of the secondary beam spots.
   33. The method of any of clauses 27-32, wherein causing the outlier charged particles of the each secondary charged-particle beam to not be detected by the detector comprises:
adjusting a beam limiting aperture configuration to cause a beam limiting aperture of the beam limiting aperture configuration to be positioned upstream to the detector to filter the outlier charged particles.
   34. The method of clause 33, wherein adjusting the beam limiting aperture configuration comprises:
adjusting the beam limiting aperture configuration to cause the beam limiting aperture of the beam limiting aperture configuration to be positioned upstream to the lens and to filter the outlier charged particles.
   35. The method of any of clauses 33-34, wherein refocusing the lens to adjust the currents comprises:
based on an aperture size of the beam limiting aperture, refocusing the lens to adjust the currents.
   36. The method of any of clauses 33-35, wherein refocusing the lens to adjust the currents comprises:
based on a position of the beam limiting aperture along a projection axis of the lens, refocusing the lens to adjust the currents.
   37. The method of any of clauses 27-36, wherein the detector is a pixelated detector, and wherein causing the outlier charged particles of the each secondary charged-particle beam to not be detected by the detector comprises:
selecting a subset of pixels from pixels covered by the each secondary charged-particle beam.
   38. The method of any of clauses 27-37, wherein the detector is a pixelated detector, and wherein refocusing the lens to adjust the currents of the plurality of secondary charged-particle beams detected by the detector comprises:
based on a detector cell size of the pixelated detector, refocusing the lens to adjust the currents.
   39. The method of any of clauses 27-28, wherein refocusing the lens to adjust the currents comprises: refocusing the lens to cause a focal point of the lens to move towards or away from a plane of the detector for a first step distance;
determining whether a value of the collection efficiency increases and whether a value of a crosstalk ratio is below a predetermined threshold; and
based on a determination that the value of the collection efficiency increases and a determination that the value of the crosstalk ratio is below the predetermined threshold, refocusing the lens to cause the focal point of the lens to move towards or away from the plane of the detector for a second step distance.
   40. The method of clause 39, further comprising:
based on a determination that the value of the collection efficiency decreases, changing a scanning direction of the multi-beam inspection apparatus.
   41. The method of clause 39, further comprising:
based on a determination that the value of the collection efficiency does not increase or a determination that the value of the crosstalk ratio is not below the predetermined threshold, stopping refocusing the lens.

The block diagrams in the figures illustrate the architecture, functionality, and operation of possible implementations of systems, methods, and computer hardware or software products according to various example embodiments of the present disclosure. In this regard, each block in a flowchart or block diagram may represent a module, segment, or portion of code, which includes one or more executable instructions for implementing the specified logical functions. It should be understood that in some alternative implementations, functions indicated in a block may occur out of order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof.

1. A system, comprising:
a multi-beam inspection apparatus configured to scan a sample and comprising a lens;
a detector configured to receive a plurality of secondary charged-particle beams in response to scanning the sample; and
a controller including circuitry communicatively coupled to the multi-beam inspection apparatus and the detector, the controller configured to:
focus the lens to adjust sizes of secondary beam spots, wherein the secondary beam spots are formed by the plurality of secondary charged-particle beams on the detector;
cause, for each secondary charged-particle beam of the plurality of secondary charged-particle beams, outlier charged particles of the each secondary charged-particle beam to not be detected by the detector; and
refocus the lens to adjust currents of a portion of the plurality of secondary charged-particle beams detected by the detector, wherein the outlier charged particles do not contribute to the currents.

2. The system of claim 1, wherein the controller is configured to focus the lens to adjust the sizes of the secondary beam spots to enable minimizing the sizes of the secondary beam spots.

3. The system of claim 1, wherein the controller is configured to refocus the lens to adjust the currents to enable maximizing the currents of the portion of the plurality of secondary charged-particle beams detected by the detector.

4. The system of claim 1, wherein the detector is a pixelated detector, and the controller is configured to cause the outlier charged particles of the each secondary charged-particle beam to not be detected by adjusting a number of pixels of a detector cell of the detector, wherein the pixels of the detector cell are configured to detect the plurality of secondary charged-particle beams.

5. The system of claim 1, wherein the controller is configured to focus the lens to adjust the sizes of the secondary beam spots using a first beam focusing method, and the first beam focusing method comprises one of:
focusing of the lens to cause paraxial rays of the plurality of secondary charged-particle beams to focus on a plane of the detector;
focusing of the lens to position ellipses of least confusion of the plurality of secondary charged-particle beams on the plane of the detector to form the secondary beam spots; or focusing of the lens to minimize rising-edge widths of the secondary beam spots.

6. The system of claim 5, wherein the controller is configured to refocus the lens to adjust the currents using a second beam focusing method different from the first beam focusing method, and the second beam focusing method comprises one of:
focusing of the lens to cause the paraxial rays of the plurality of secondary charged-particle beams to focus on the plane of the detector;
focusing of the lens to position the ellipses of least confusion of the plurality of secondary charged-particle beams on the plane of the detector to form the secondary beam spots; or focusing of the lens to minimize the rising-edge widths of the secondary beam spots.

7. The system of claim 1, wherein the controller is configured to cause the outlier charged particles of the each secondary charged-particle beam to not be detected by the detector by adjusting a beam limiting aperture configuration to cause a beam limiting aperture of the beam limiting aperture configuration to be positioned upstream to the detector and to filter the outlier charged particles.

8. The system of claim 7, wherein the controller is configured to cause the outlier charged particles of the each secondary charged-particle beam to not be detected by the detector by adjusting the beam limiting aperture configuration to cause the beam limiting aperture of the beam limiting aperture configuration to be positioned upstream to the lens and to filter the outlier charged particles.

9. The system of claim 7, wherein the controller is configured to refocus the lens to adjust the currents to enable, based on an aperture size of the beam limiting aperture, refocusing of the lens to adjust the currents.

10. The system of claim 7, wherein the controller is configured to refocus the lens to adjust the currents to enable, based on a position of the beam limiting aperture along a projection axis of the lens, refocusing of the lens to adjust the currents.

11. The system of claim 1, wherein the detector is a pixelated detector, and the controller is configured to cause the outlier charged particles of the each secondary charged-particle beam to not be detected by the detector by selecting a subset of pixels from pixels covered by the each secondary charged-particle beam.

12. The system of claim 1, wherein the detector is a pixelated detector, and the controller is configured to refocus the lens to adjust the currents to enable, based on a detector cell size of the pixelated detector, refocusing of the lens to adjust the currents.

13. The system of claim 1, wherein the controller is configured to refocus the lens to adjust the currents to enable refocusing of the lens to cause a focal point of the lens to move towards or away from a plane of the detector for a first step distance;
determine whether a value of collection efficiency increases and whether a value of a crosstalk ratio is below a predetermined threshold;
based on a determination that the value of the collection efficiency increases and a determination that the value of the crosstalk ratio is below the predetermined threshold, refocus the lens to cause the focal point of the lens to move towards or away from the plane of the detector for a second step distance;
based on a determination that the value of the collection efficiency decreases, changing a scanning direction of the multi-beam inspection apparatus; and
based on a determination that the value of the collection efficiency reaches a maximum value or a determination that the value of the crosstalk ratio is not below the predetermined threshold, stop refocusing the lens.

14. A non-transitory computer-readable medium that stores a set of instructions that is executable by at least one processor of a multi-beam inspection apparatus to cause the multi-beam inspection apparatus to perform operations comprising:
focusing a lens of the multi-beam inspection apparatus to adjust sizes of secondary beam spots, wherein the secondary beam spots are formed by a plurality of secondary charged-particle beams on a detector;
causing, for each secondary charged-particle beam of the plurality of secondary charged-particle beams, outlier charged particles of the each secondary charged-particle beam to not be detected by the detector; and
refocusing the lens to adjust currents of a portion of the plurality of secondary charged-particle beams detected by the detector, wherein the outlier charged particles do not contribute to the currents.

15. The non-transitory computer-readable medium of claim 14, wherein focusing the lens of the multi-beam inspection apparatus to adjust the sizes of the secondary beam spots comprises:
minimizing the sizes of the secondary beam spots.

16. The non-transitory computer-readable medium of claim 14, wherein refocusing the lens to adjust the currents comprises:
maximizing the currents of the portion of the plurality of secondary charged-particle beams detected by the detector.

17. The non-transitory computer-readable medium of claim 14, wherein the detector is a pixelated detector, and wherein causing the outlier charged particles of the each secondary charged-particle beam to not be detected by the detector comprises:
adjusting a number of pixels of a detector cell of the detector, wherein the pixels of the detector cell are configured to detect the plurality of secondary charged-particle beams.

18. The non-transitory computer-readable medium of claim 14, wherein focusing the lens of the multi-beam inspection apparatus to adjust the sizes of the secondary beam spots comprises a first beam focusing method, and the first beam focusing method comprises one of:
focusing the lens to cause paraxial rays of the plurality of secondary charged-particle beams to focus on a plane of the detector;
focusing the lens to position ellipses of least confusion of the plurality of secondary charged-particle beams on the plane of the detector to form the secondary beam spots; or focusing the lens to minimize rising-edge widths of the secondary beam spots.

19. The non-transitory computer-readable medium of claim 14, wherein refocusing the lens to adjust the currents comprises a second beam focusing method different from a first beam focusing method, and the second beam focusing method comprises one of:
focusing the lens to cause paraxial rays of the plurality of secondary charged-particle beams on a plane of the detector;
focusing the lens to position ellipses of least confusion of the plurality of secondary charged-particle beams on the plane of the detector to form the secondary beam spots; or
focusing the lens to minimize rising-edge widths of the secondary beam spots.

20. A method of optimizing collection efficiency of secondary charged particles, comprising:
focusing a lens of a multi-beam inspection apparatus to adjust sizes of secondary beam spots, wherein the secondary beam spots are formed by a plurality of secondary charged-particle beams on a detector;
causing, for each secondary charged-particle beam of the plurality of secondary charged-particle beams, outlier charged particles of the each secondary charged-particle beam to not be detected by the detector; and
refocusing the lens to adjust currents of a portion of the plurality of secondary charged-particle beams detected by the detector, wherein the outlier charged particles do not contribute to the currents.
